(19) United States
(12) Patent Application Publication
(10) Pub. No.: US 2017/0033087 A1
(43) Pub. Date: Feb. 2, 2017

(54) STACK SEMICONDUCTOR PACKAGE STRUCTURE AND METHOD OF MANUFACTURING THE SAME

(71) Applicant: Samsung Electronics Co., Ltd., Suwon-si (KR)

(72) Inventor: Zhengrong CHEN, Nanjing (CN)

(21) Appl. No.: 15/224,490

(22) Filed: Jul. 29, 2016

(30) Foreign Application Priority Data
Jul. 31, 2015 (CN) 201510464260.9
Nov. 17, 2015 (KR) 10-2015-0161044

(51) Int. Cl. H01L 25/065; H01L 23/00; H01L 25/00

(52) U.S. Cl. CPC H01L 25/0657; H01L 25/50; H01L 24/73; H01L 2225/06568; H01L 2225/06562; H01L 2225/06506; H01L 2225/06517; H01L 2225/0652; H01L 2224/73207

(57) ABSTRACT

A stack semiconductor package structure includes a substrate; a second chip comprising a plurality of conductive bumps formed on a surface thereof; and a first chip positioned on the second chip, wherein the second chip is electrically connected to the substrate through the plurality of conductive bumps in a flip-chip manner, and wherein the first chip is electrically connected to the second chip through a plurality of bonding wires.

### CROSS-REFERENCE TO RELATED APPLICATION

This application claims the benefit of Chinese Patent Application No. 10464260.9, filed on Jul. 31, 2015, in the State Intellectual Property Office of the People's Republic of China and Korean Patent Application No. 10-2015-0161044, filed on Nov. 17, 2015, in the Korean Intellectual Property Office, the disclosures of which are incorporated herein in their entirety by reference.

### BACKGROUND

The inventive concept relates to a semiconductor package structure and a method of manufacturing the semiconductor package structure, and more particularly, to a stack semiconductor package structure and a method of manufacturing the semiconductor package structure.

A package-on-package (POP) stack semiconductor package has a relatively long communication path between a plurality of stacked chips, it is generally difficult to significantly reduce the overall size of the POP stack package. Thus, there are limitations in improving the heat dissipation properties while increasing the speed of signal transmission.

It is also difficult to measure whether chips are good or bad in a three-dimensional (3D) stack semiconductor package, and the 3D stack semiconductor package employs through silicon vias (TSVs), thus causing a low yield and high manufacturing costs. Further, the 3D stack semiconductor package cannot have a circuit formed in regions of chips occupied by TSVs.

### SUMMARY

The inventive concept provides a stack semiconductor package structure capable of securing improved quality of chips and reducing a package size.

The inventive concept also provides a method of manufacturing the stack semiconductor package structure described above.

According to an aspect of the inventive concept, there is provided a stack semiconductor package structure including a substrate; a second chip including a plurality of conductive bumps formed on a surface thereof; and a first chip positioned on the second chip, wherein the second chip is electrically connected to the substrate through the plurality of conductive bumps in a flip-chip manner, and wherein the first chip is electrically connected to the second chip through a plurality of bonding wires.

According to another aspect of the inventive concept, there is provided a stack semiconductor package structure including a substrate; a flip chip mounted on the substrate and electrically connected to the substrate through a plurality of conductive bumps; and at least one stack chip attached on the flip chip and electrically connected to the flip chip through a plurality of bonding wires.

A plurality of sub chips included in the second chip group may be electrically connected to each other through the plurality of bonding wires, and a plurality of sub chips included in the first chip group may be electrically connected to each other through the plurality of bonding wires.

According to another aspect of the inventive concept, there is provided a stack semiconductor package structure including: a substrate; a flip chip mounted on the substrate, including a first surface and a second surface opposite to the first surface, mounted on the substrate by locating the first surface in a lower direction, and electrically connected to the substrate through a plurality of conductive bumps formed on the first surface; and at least one stack chip mounted on the second surface of the flip chip, including a third surface and a fourth surface opposite to the third surface, mounted on the second surface of the flip chip by locating the third surface in a lower direction, and electrically connected to the flip chip through a plurality of bonding wires.

According to another aspect of the inventive concept, there is provided a method of manufacturing a stack semiconductor package structure including: forming a first chip on a carrier; forming a second chip having a plurality of conductive bumps formed on an upper surface thereof on the first chip; electrically connecting the first chip and the second chip through a plurality of bonding wires; electrically connecting the second chip to a substrate in a flip-chip manner through the plurality of conductive bumps; and removing the carrier.

According to another aspect of the inventive concept, there is provided a method of manufacturing a stack semiconductor package structure including forming at least one stack chip on a carrier; forming a flip chip having a plurality of conductive bumps formed on an upper surface thereof on the at least one chip; electrically connecting the at least one stack chip and the flip chip through a plurality of bonding wires; electrically connecting the flip chip to a substrate in a flip-chip manner through the plurality of conductive bumps; and removing the carrier.

In some embodiments, a stack semiconductor package structure comprises: a package substrate; a second chip flip-chip bonded to the package substrate; and a first chip stacked on the second chip, where a portion of the first chip is not overlapped with the second chip, exposing a portion of an upper surface of the first chip, and the first chip is electrically connected to the second chip through a conductive connection member extending between the exposed upper surface of the first chip and a bonding pad of the second chip.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view illustrating a stack semiconductor package structure according to an embodiment;

FIGS. 2 and 3 are respectively a cross-sectional view and a plan view for describing a layout relationship of a first chip and a second chip of FIG. 1;

FIG. 4 is a plan view for describing a stack and electrical connection relationship of a first chip and a second chip of a stack semiconductor package structure according to an embodiment;

FIGS. 5 through 10 are cross-sectional views for describing a method of manufacturing a stack semiconductor package structure according to an embodiment;

FIG. 11 is a cross-sectional view illustrating a stack semiconductor package structure according to another embodiment;

FIG. 12 is a plan view for describing a stack and electrical connection relationship of a first chip, a second chip, and a third chip of FIG. 11;

FIG. 13 is a cross-sectional view illustrating a stack semiconductor package structure according to another embodiment;

FIG. 14 is a plan view for describing a stack and electrical connection relationship of a first chip, a second chip, and a third chip of FIG. 13;

FIG. 15 is a cross-sectional view illustrating a stack semiconductor package structure according to another embodiment;

FIGS. 16 and 17 are respectively a cross-sectional view and a plan view for describing a layout relationship of a flip chip and stack chips of FIG. 15;

FIGS. 18 through 20 are cross-sectional views for describing a method of manufacturing a stack semiconductor package structure according to another embodiment;

FIG. 21 is a cross-sectional view illustrating a stack semiconductor package structure according to another embodiment;

FIG. 22 is a cross-sectional view illustrating a stack semiconductor package structure according to another embodiment;

FIG. 23 is a plan view for describing a layout relationship of a flip chip and stack chips of FIG. 22;

FIG. 24 is a cross-sectional view illustrating a stack semiconductor package structure according to another embodiment;

FIG. 25 is a schematic plan view of a semiconductor module including a stack semiconductor package structure according to an embodiment;

FIG. 26 is a schematic diagram showing a card including a stack semiconductor package structure according to an embodiment;

FIG. 27 is a schematic block diagram showing an electronic circuit board including a stack semiconductor package structure according to an embodiment;

FIG. 28 is a schematic block diagram showing an electronic system including a stack semiconductor package structure according to an embodiment;

FIG. 29 is a schematic diagram showing an electronic system including a stack semiconductor package structure according to an embodiment; and

FIG. 30 is a schematic perspective view of an electronic system including a stack semiconductor package structure according to an embodiment.

### DETAILED DESCRIPTION OF THE EMBODIMENTS_{—}

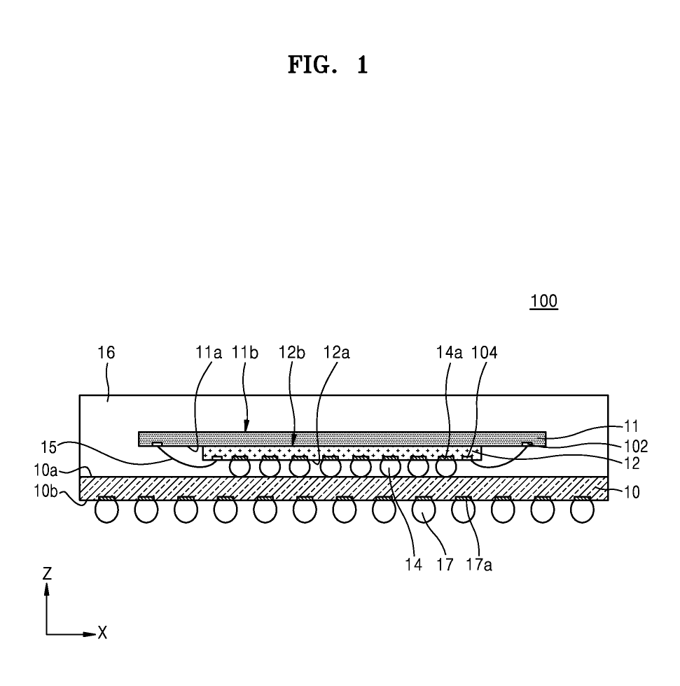

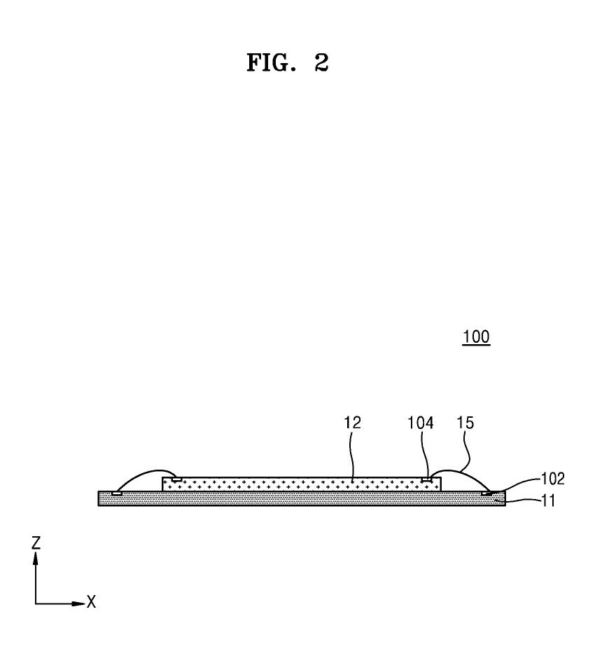

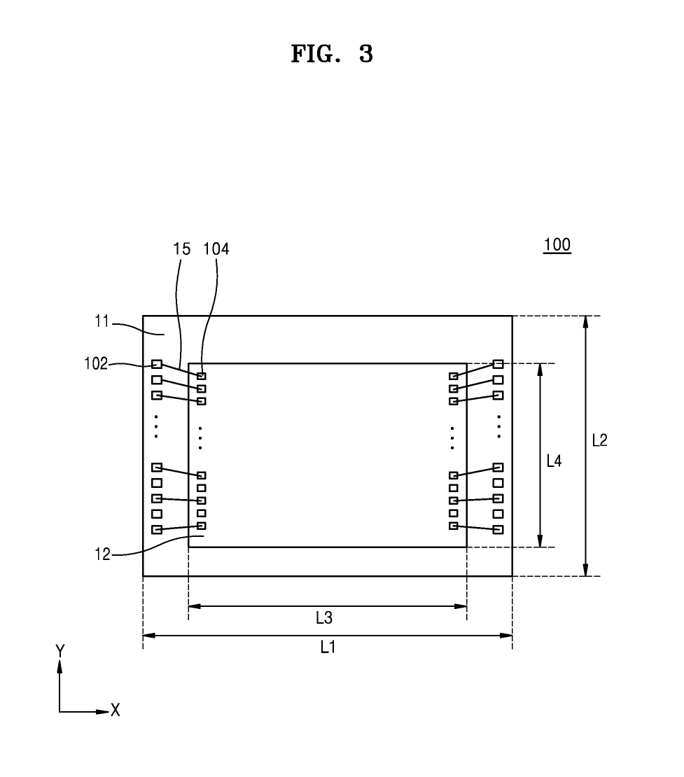

FIG. 1 is a cross-sectional view illustrating a stack semiconductor package structure 100 according to an embodiment. FIGS. 2 and 3 are a cross-sectional view and a plan view, respectively, illustrating an arrangement of a first chip 11 and a second chip 12 of FIG. 1.

More specifically, FIG. 1 is a cross-sectional view for describing an overall structure of the stack semiconductor package structure 100. FIG. 2 is a cross-sectional view of the stack semiconductor package structure 100 in which the first chip 11 and the second chip 12 of FIG. 1 are flipped in order to place the second chip 12 on top. FIG. 3 is a plan view for illustrating a stack and electrical relationship of the first chip 11 and the second chip 12 of FIG. 2.

As shown in FIG. 1, the stack semiconductor package structure 100 may include a substrate 10, the second chip 12 having a plurality of conductive bumps such as a plurality of solder bumps 14 formed on a surface thereof, and the first chip 11 positioned above the second chip 12.

The second chip 12 may include a first surface 12a and a second surface 12b opposite to the first surface 12a. The first chip 11 may include a third surface (or an upper surface) 11a and a fourth surface 11b (or a bottom surface) opposite to the third surface 11a. The first surface 12a and the third surface 11a may be active surfaces in which electronic circuits are formed. The second surface 12b and the fourth surface 11b may be non-active surfaces in which no electronic circuit may be formed. Active surfaces of the first chip 11 and the second chip 12 may be formed on a lower or bottom surface of the chips.

The second chip 12 may be electrically connected to the substrate 10 in a flip-chip manner through the plurality of solder bumps 14. Thus, the second chip 12 may be referred to as a flip chip. Reference numeral 14a of FIG. 1 may be a solder bump pad.

As shown in FIG. 1, the first chip 11 may be stacked on the second chip 12. Thus, the first chip 11 may be referred to as a stack chip. The stack semiconductor package structure 100 of FIG. 1 includes only one stack chip. However, a plurality of stack chips may be included in the stack semiconductor package as will be described later.

The first chip 11 may be connected to the second chip 12 through bonding wires 15. A bonding pad 104 of the second chip 12 may be electrically connected to a bonding pad 102 of the first chip 11 through the bonding wires 15.

The substrate 10 may include a printed circuit board (PCB), a silicon substrate, a sapphire substrate or the like, but the inventive concept is not limited to the substrate 10 described above. As will be recognized by those skilled in the art, any suitable material may be selected for the substrate 10 and is within the spirit and scope of the inventive concept.

According to some embodiments, the second chip 12 may be a chip for providing a high-speed signal. The second chip 12 may be a logic chip processing the high-speed signal and may include many input pins and output pins. The plurality of solder bumps 14 may be formed on a lower surface of the second chip 12.

According to an embodiment, the first chip 11 may be a memory chip. Although not illustrated in FIGS. 1 and 2, the first chip 11 may be attached to the second chip 12 through an adhesive. The adhesive may include a thermosetting adhesive, a thermoplastic adhesive, a chip adhesion film, a conductive silver paste and so on.

The plurality of solder bumps 14 may be formed by substantially the same process as the process of forming welding spots of a flip chip. The plurality of conductive bumps such as the plurality of solder bumps 14 may also include copper pillars, gold bumps and so on.

If the second chip 12 is a logic chip, the logic chip (which may have many input and output pins) may be connected to the substrate 10 in a flip-chip manner. When the stack semiconductor package structure 100 includes the logic chip, since through silicon vias are not formed in the stack semiconductor package structure 100, it is unnecessary to redesign the logic chip.

According to some embodiments, the first chip 11 may be larger than the second chip 12 as illustrated in FIG. 3. As shown in FIGS. 1 and 2, a first dimension (i.e., a length or a width) L1 of the first chip 11 in a horizontal direction (X direction) and a second dimension L2 thereof in a vertical direction (Y direction) may be greater than a third dimension L3 of the second chip 12 in the horizontal direction (X direction) and a fourth dimension L4 thereof in the vertical direction (Y direction). The stack semiconductor package structure 100 may be disposed such that the first chip 11 constituting the stack chip substantially entirely covers the second chip 12 constituting the flip chip, as shown, for example, in FIG. 3.

The inventive concepts are not limited to the sizes of the first chip 11 and the second chip 12 illustrated in the embodiment of FIGS. 1 through 3. For example, as shown in FIGS. 1 through 3, the boding pads 102 of the first chip 11 may be exposed to permit connection to the bonding wires 15, and thus the second chip 12 may be smaller than the first chip 11. However, other arrangements may be possible as explained further below.

The first chip 11 and the second chip 12 may be electrically connected to each other through the bonding wires 15, thereby allowing communication between the first and second chips 11 and 12. As illustrated in FIG. 1, the bonding wires 15 may not be in contact with an upper surface 10a of the substrate 10 and may be spaced apart from the substrate 10. The bonding wires 15 may not be electrically connected to the substrate 10.

According to an embodiment, the stack semiconductor package structure 100 may further include an encapsulant (or an encapsulating member) 16 protecting the first chip 11, the second chip 12, the substrate 10 and so on. The encapsulant 16 may be formed to encapsulate and protect the first and second chips 11 and 12 and the substrate 10. The encapsulant 16 may be formed as a polymer layer such as resin. The encapsulant 16 may include, for example, an epoxy molding compound (EMC). The encapsulant 16 may be referred to as a molding layer.

According to some embodiments, the stack semiconductor package structure 100 may further include solder balls 17 disposed on a lower surface 10b of the substrate 10. For example, the solder balls 17 may be formed in the lower surface 10b of the substrate 10 through a bumping process. Thus, the first and second chips 11 and 12 may be electrically connected to other circuits. In FIG. 1, reference numeral 17a may be a solder ball pad.

According to some embodiments, the first chip 11 and the second chip 12 may be electrically connected to each other via the bonding wires 15 to permit mutual signal transmission. The second chip 12 may be connected to the substrate 10 through the solder bumps 14 to perform high-speed signal transmission without delaying signals.

According to some embodiments, an electrical connection between the first chip 11 and the second chip 12, i.e., a connection between different chips, may be made using bonding wires, and the first chip 11, i.e., the flip chip, may be electrically connected to the substrate 10 in a flip-chip manner. Thus, the stack semiconductor package structure 100 may be formed using the chips 11 and 12, i.e., where the first chip 11 and the second chip 12 may each be formed with high quality.

When comparing the stack semiconductor package structure 100 with a POP stack semiconductor package structure, the stack semiconductor package structure 100 may include only one substrate, and thus the size of the stack semiconductor package structure 100 may be reduced. Also, the plurality of chips 11 and 12 are electrically connected through the bonding wires 15. Therefore, other intermediate medium layers such as an air layer for promoting heat dissipation may not be required.

When comparing the stack semiconductor package structure 100 with the POP stack semiconductor package, in the stack semiconductor package structure 100 of the inventive concept, the electrical connection is made between the chips 11 and 12 through the bonding wires 15. Thus, an interface through which a signal passes may be reduced, thereby improving the efficiency of the signal transmission. Further, when comparing the stack semiconductor package structure 100 with a 3D stack semiconductor package, the stack semiconductor package structure 100 of the inventive concept has no through silicon via, and thus there is no need to redesign the logic chip, thereby reducing manufacturing costs.

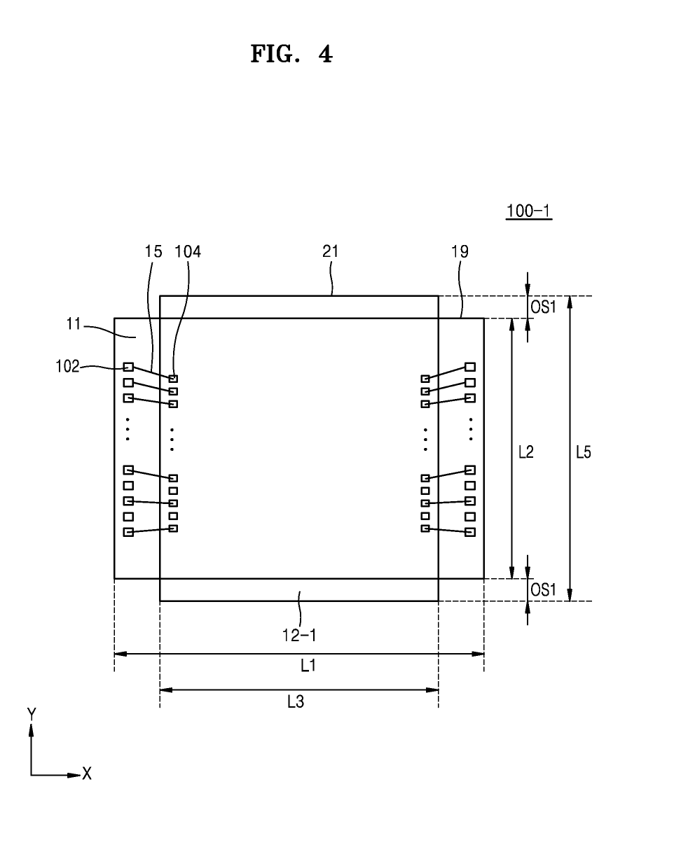

FIG. 4 is a plan view illustrating a stack and electrical connection relationship of the first chip 11 and a second chip 12-1 of a stack semiconductor package structure 100-1 according to an embodiment.

More specifically, the stack semiconductor package structure 100-1 of FIG. 4 may be substantially the same as the stack semiconductor package structure 100 of FIGS. 1 through 3, except for a change in the size of the second chip 12-1. The same reference numerals denote the same elements.

In the stack semiconductor package structure 100-1, the first chip 11 may be stacked on the second chip 12-1 (i.e., a flip chip). FIG. 4 illustrates the second chip 12-1 stacked on the first chip 11 for comparison with FIG. 3. The bonding pad 102 of the first chip 11 may be electrically connected to the bonding pad 104 of the second chip 12-1 through the bonding wires 15.

A first dimension (i.e., a length or a width) of the first chip 11 in a horizontal direction (X direction) and a second dimension thereof in a vertical direction (Y direction) may be respectively L1 and L2. A third dimension (i.e., a length or a width) of the second chip 12-1 in the horizontal direction (X direction) and a fourth dimension (i.e., a length or a width) thereof in the vertical direction (Y direction) may be respectively L3 and L5.

In the stack semiconductor package structure 100-1, as shown in FIG. 4, the length (or the width) L2 of the first chip 11 in the vertical direction (Y direction) may be smaller than the length (or the width) L5 of the second chip 12-1 in the vertical direction (Y direction).

Accordingly, in the stack semiconductor package structure 100-1, the second chip 12-1 may be stacked on the first chip 11 with an offset OS1 in the vertical direction (Y direction) as compared with FIG. 3. In other words, the first chip 11 may cover only a part of the second chip 12-1 constituting the flip chip in the stack semiconductor package structure 100-1. Thus, an edge 21 of the second chip 12-1 may therefore be offset from a corresponding edge 19 of the first chip 11 by an amount of the offset OS1.

When necessary, the length (or the width) L5 of the second chip 12-1 in the vertical direction (Y direction) may be smaller than the length (or the width) L2 of the first chip 11 in the vertical direction (Y direction), and the bonding wires 15 may be disposed in the vertical direction (Y direction). The stack semiconductor package structure 100-1 may be disposed to have the offset OS1 such that the bonding pad 102 of the first chip 11 and the bonding pad 104 of the second chip 12-1 are connected to each other by the bonding wires 15.

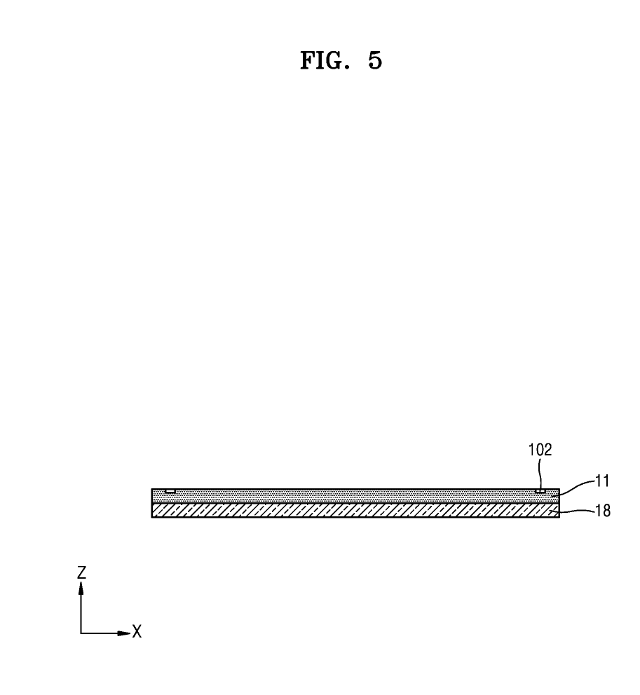

A method of manufacturing the stack semiconductor package structure 100 shown in FIG. 1 will now be described in detail with reference to FIGS. 5 through 10.

FIGS. 5 through 10 are cross-sectional views for describing a method of manufacturing the stack semiconductor package structure 100 according to an embodiment.

Referring to FIG. 5, the first chip 11 may be formed on a carrier 18. The first chip 11 may include bonding pads 102 on edge portions thereof. Although not illustrated in FIG. 5, the first chip 11 may be attached to the carrier 18 using a removable adhesive coated on an upper surface of the carrier 18. Examples of the removable adhesive may include a photosensitive material (for example, a thin film material whose viscosity is reduced by radiation of an ultraviolet light), a hot melt adhesive, etc.

According to an exemplary embodiment, the first chip 11 may be a memory chip. The carrier 18 may be formed of a glass plate, a thermal conductive metal plate, etc., but the inventive concept is not limited thereto. The carrier 18 may be selected based on the selection of the adhesive material. For example, a glass plate may use an UV sensitive adhesive material as an adhesive.

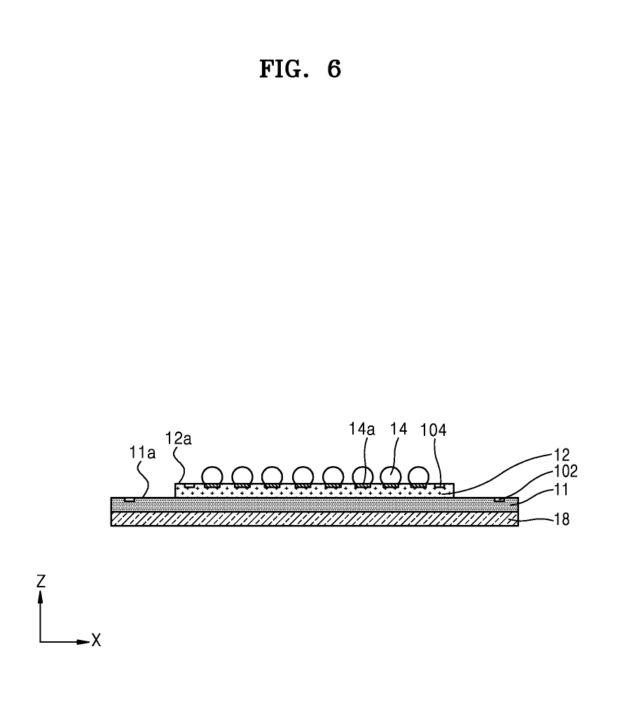

Referring to FIG. 6, the second chip 12 may be stacked on the first chip 11. The second chip 12 may include the bonding pad 104. The plurality of solder bumps 14 may be formed on the upper surface 12a of the second chip 12. The plurality of solder bumps 14 may be formed on the solder bump pads 14a.

The second chip 12 may be attached to the first chip 11 by using an adhesive (not illustrated) such as a thermosetting adhesive, a thermoplastic adhesive, a chip adhesion film, a conductive silver paste and so on, coated on the third surface (or the upper surface) 11a of the first chip 11. The second chip 12 may be a chip for a high-speed signal. In particular, the second chip 12 may be a logic chip processing a high-speed signal and having a large number of input and output pins.

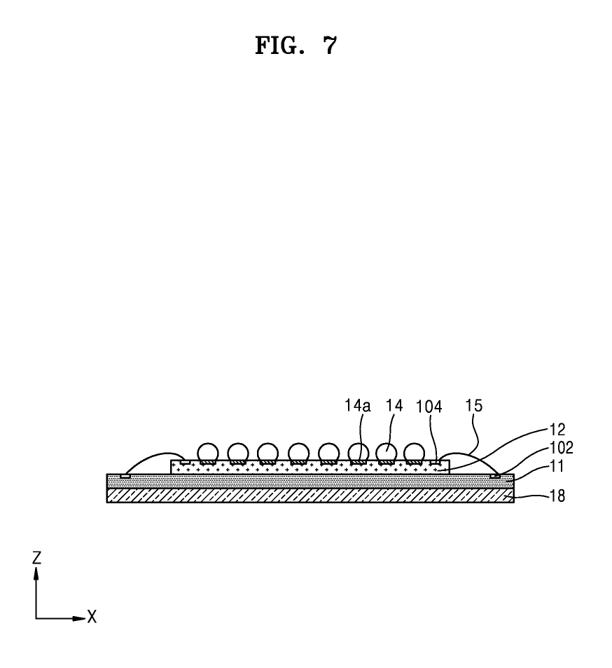

Referring to FIG. 7, the first chip 11 may be electrically connected to the second chip 12 through the bonding wires 15. The bonding pad 104 of the second chip 12 and the bonding pad 102 of the first chip 11 may be electrically connected to each other through the bonding wires 15. As illustrated in FIG. 7, the highest point of each of the bonding wires 15 may be lower than a highest point of the plurality of solder bumps 14 to prevent the bonding wires 15 from contacting the substrate 10 during a subsequent flip chip bonding process.

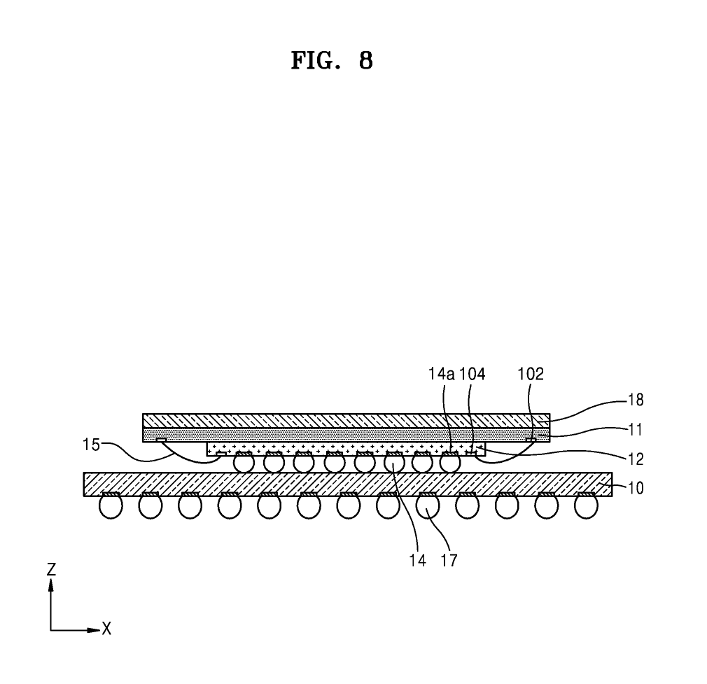

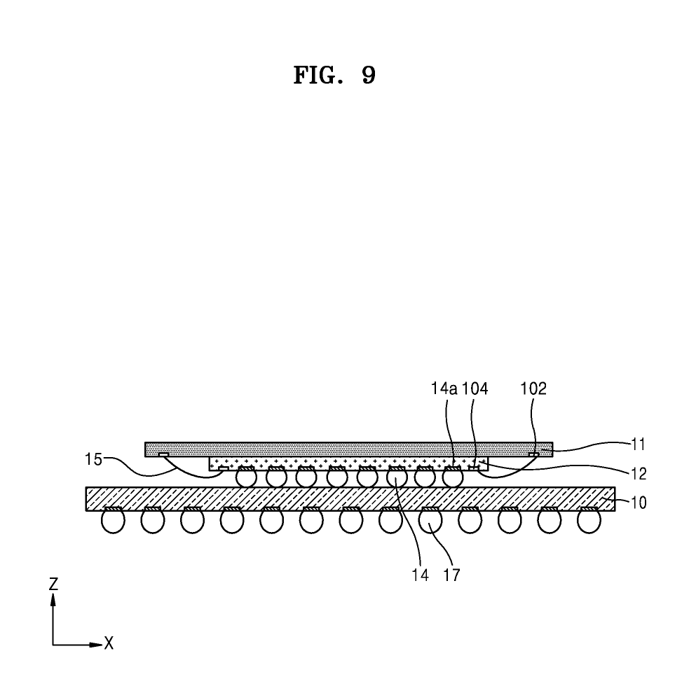

Referring to FIGS. 8 and 9, the second chip 12 may be electrically connected to the substrate 10 in a flip-chip manner through the plurality of solder bumps 14 by flipping over the first chip 11 and the second chip 12 formed on the carrier 18 as shown in FIG. 8. The bonding wires 15 may not be in contact with the substrate 10 and may be spaced apart from the substrate 10. If the second chip 12 is a logic chip, the logic chip having a large number of input and output pins may be electrically connected to the substrate 10 in a flip-chip manner, i.e., using a flip-chip bonding technique.

As shown in FIG. 9, the carrier 18 may be removed. For example, the carrier 18 may be removed by melting a hot melt adhesive by heating. The carrier 18 may be removed by reducing viscosity of a photosensitive adhesion layer by radiation of an ultraviolet light. However, the inventive concept is not limited thereto.

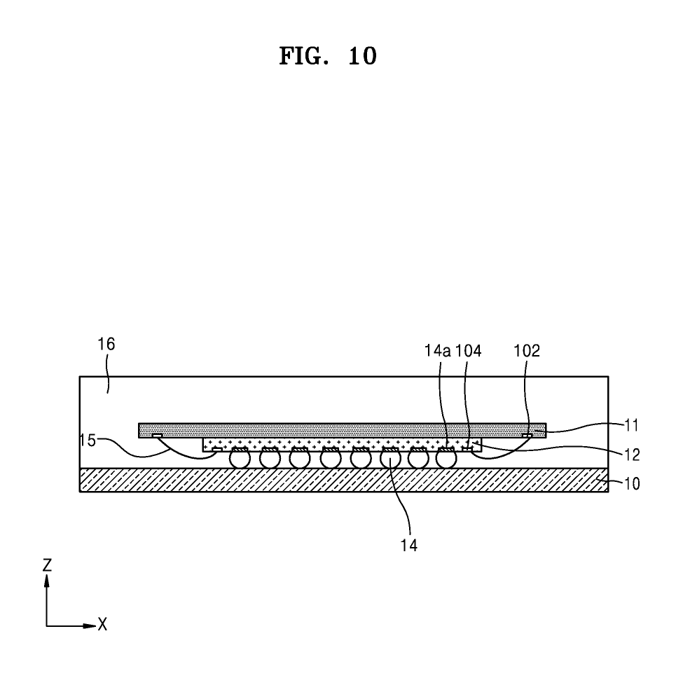

Referring to FIG. 10, the first chip 11, the second chip 12, and the substrate 10 are encapsulated by the encapsulant 16 using a molding process. The encapsulant 16 may be provided to protect the first chip 11, the second chip 12, and the substrate 10.

Then, as shown in FIG. 1, the solder balls 17 may be formed on a lower surface 10b of the substrate 10. For example, the solder balls 17 may be formed through a bumping process in the lower surface 10b of the substrate 10 such that the chips 11 and 12 may be connected to other circuits.

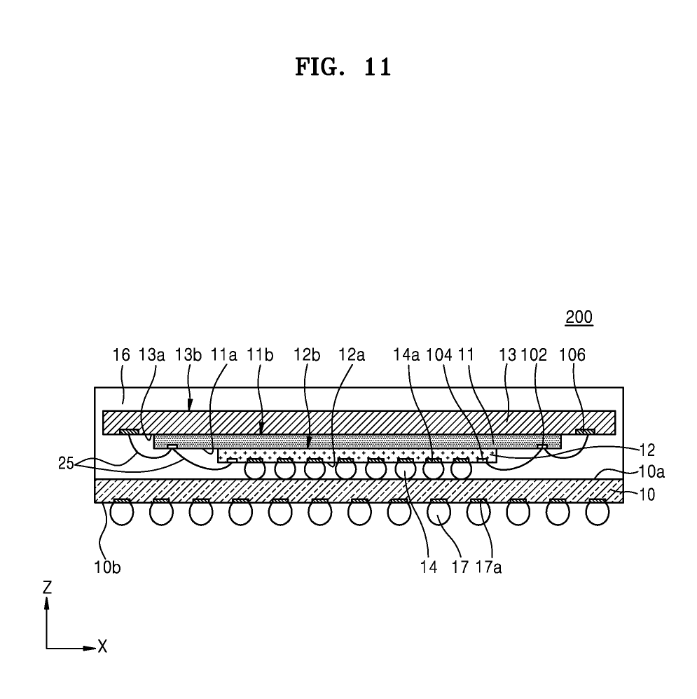

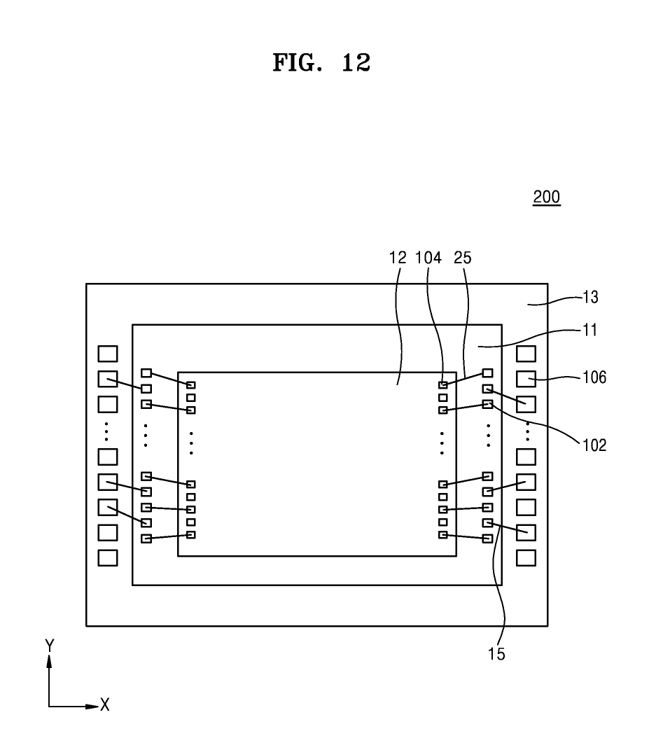

FIG. 11 is a cross-sectional view illustrating a stack semiconductor package structure 200 according to another embodiment. FIG. 12 is a plan view illustrating a stack and electrical connection relationship of the first chip 11, the second chip 12, and a third chip 13 of FIG. 11.

More specifically, FIG. 11 is a cross-sectional view for describing an overall structure of the stack semiconductor package structure 200. FIG. 12 is a plan view illustrating the first chip 11, the second chip 12, and the third chip 13 of FIG. 11.

The stack semiconductor package structure 200 of FIGS. 11 and 12 may be the same as the stack semiconductor package structure 100 of FIGS. 1 through 3, except that the third chip 13 is attached on the first chip 11, and the first chip 11 and the third chip 13 are electrically connected to each other by bonding wires 25.

Descriptions of elements of the stack semiconductor package structure 200 of FIGS. 11 and 12 may be omitted or briefly provided with reference to the stack semiconductor package structure 100 of FIGS. 1 through 3. Differences between the stack semiconductor package structure 200 of FIGS. 11 and 12 and the stack semiconductor package structure 100 of FIGS. 1 through 3 will be explained.

As illustrated in FIG. 11, the stack semiconductor package structure 200 may include the substrate 10, the second chip 12 having the plurality of solder bumps 14 formed on a surface thereof, the first chip 11 stacked on the second chip 12 and thus positioned above the second chip 12, and the third chip 13 stacked on the first chip 11 and thus positioned above the first chip 11.

The second chip 12 may be electrically connected to the substrate 10 in a flip-chip (or up-side down) manner through the plurality of solder bumps 14. The third chip 13 may be electrically connected to the first chip 11 through the bonding wires 25. A bonding pad 106 of the third chip 13 may be electrically connected to the bonding pad 102 of the first chip 11 through the bonding wires 15.

The first chip 11 may be electrically connected to the second chip 12 through the bonding wires 25. The bonding pad 104 of the second chip 12 may be electrically connected to the bonding pad 102 of the first chip 11 through the bonding wires 25.

The second chip 12 may include the first surface 12a and the second surface 12b opposite to the first surface 12a. The first chip 11 may include the third surface 11a and the fourth surface 11b opposite to the third surface 11a. The third chip 13 may include a fifth surface 13a and a sixth surface 13b opposite to the fifth surface 13a.

The first surface 12a, the third surface 11a, and the fifth surface 13a may be active surfaces in which electronic circuits are formed. The second surface 12b, the fourth surface 11b, and the sixth surface 13b may be non-active surfaces in which no electronic circuits are formed. Active surfaces of the first chip 11, the second chip 12, and the third chip 13 may be formed on a lower surface that faces the upper surface 10a of the substrate 10.

According to an embodiment, the second chip 12 may be a logic chip for a high-speed signal and having a large number of input and output pins. The first chip 11 may be a memory chip. The third chip 13 may be a memory chip or a chip having other functions, for example, a micro-electro-mechanical sensor chip.

The second chip 12 may be a flip chip to be connected to the substrate 10 through the plurality of solder bumps 14 formed on the solder bump pads 14a. An electrical connection between the first chip 11 and second chip 12 and an electrical connection between the first chip 11 and the third chip 13 may be provided by the bonding wires 25, thereby permitting communication between the chips 11, 12, and 13.

As shown in FIG. 11, the first chip 11 and the third chip 13 may be stacked on the second chip 12. Accordingly, the first chip 11 and the third chip 13 may be referred to as stack chips. Although FIG. 11 illustrates the stack semiconductor package structure 200 including two chips, i.e. the first chip 11 and the third chip 13, stack chips may be greater than two as will be described later.

The stack semiconductor package structure 200 may further include the encapsulant 16 and the solder balls 17 on the lower surface 10b of the substrate 10. The encapsulant 16 may protect the first chip 11, the second chip 12, the third chip 13, the substrate 10 and so on. The encapsulant 16 may be formed by molding the chips 11, 12, and 13 and the substrate 10. The solder balls 17 may be formed on the solder ball pads 17a formed on the lower surface 10b of the substrate 10. Thus, the first, second and third chips 11, 12, and 13 may be electrically connected to other circuits.

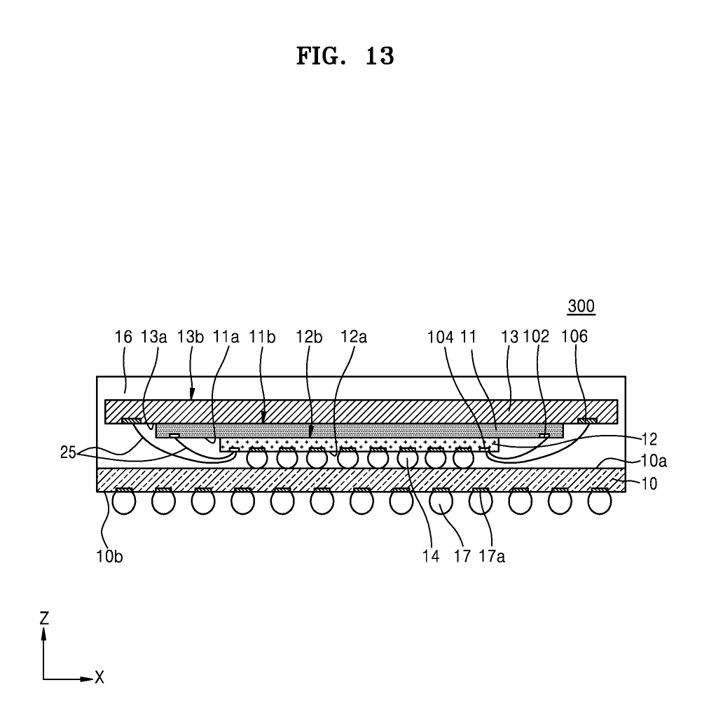

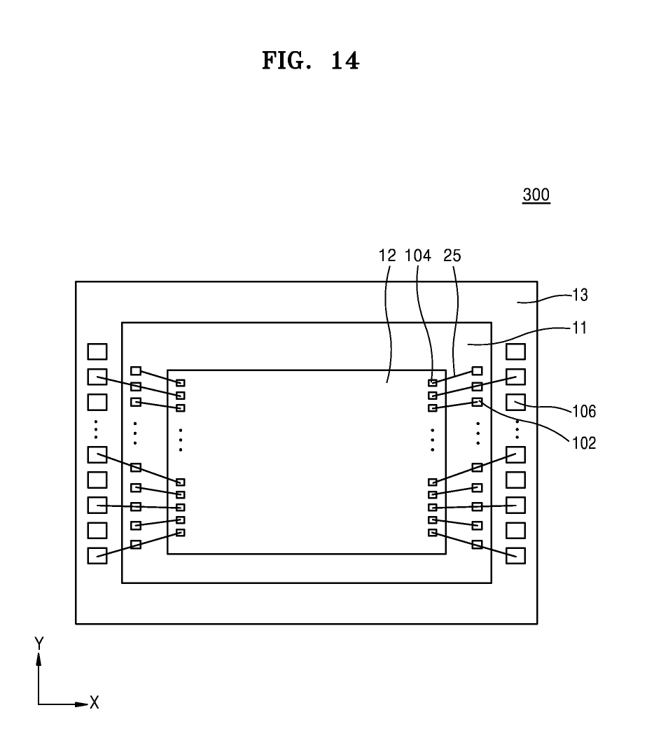

FIG. 13 is a cross-sectional view illustrating a stack semiconductor package structure 300 according to another embodiment. FIG. 14 is a plan view illustrating a stack and electrical connection relationship of the first chip 11, the second chip 12, and the third chip 13 of FIG. 13.

More specifically, FIG. 13 is a cross-sectional view for describing an overall structure of the stack semiconductor package structure 300. FIG. 14 is a plan view illustrating the first chip 11, the second chip 12, and the third chip 13 of FIG. 13.

The stack semiconductor package structure 300 of FIGS. 13 and 14 may be the same as the stack semiconductor package structure 100 of FIGS. 1 through 3, except that the third chip 13 is attached on the first chip 11, and the first chip 11 and the third chip 13 are electrically connected to each other by the bonding wires 25.

Descriptions of elements of the stack semiconductor package structure 300 of FIGS. 13 and 14 may be omitted or briefly provided with reference to the stack semiconductor package structure 100 of FIGS. 1 through 3. Differences between the stack semiconductor package structure 300 of FIGS. 13 and 14 and the stack semiconductor package structure 100 of FIGS. 1 through 3 may be emphasized.

As illustrated in FIGS. 13 and 14, the stack semiconductor package structure 300 may include the substrate 10, the second chip 12 having the plurality of solder bumps 14 formed on a surface thereof, the first chip 11 positioned above the second chip 12, and the third chip 13 positioned above the first chip 11. The second chip 12 may be electrically connected to the substrate 10 in a flip-chip manner through the plurality of solder bumps 14.

The first chip 11 may be electrically connected to the second chip 12 through the bonding wires 25. The bonding pad 102 of the first chip 11 may be electrically connected to the bonding pad 104 of the second chip 12 through the bonding wires 25. The third chip 13 may be electrically connected to the first chip 11 through the bonding wires 25. For example, the bonding pad 106 of the third chip 13 may be electrically connected to the bonding pad 104 of the second chip 12 through the bonding wires 25.

The second chip 12 may include the first surface 12a and the second surface 12b opposite to the first surface 12a. The first chip 11 may include the third surface 11a and the fourth surface 11b opposite to the third surface 11a. The third chip 13 may include the fifth surface 13a and the sixth surface 13b opposite to the fifth surface 13a.

The first surface 12a, the third surface 11a, and the fifth surface 13a may be active surfaces in which electronic circuits are formed. The second surface 12b, the fourth surface 11b, and the sixth surface 13b may be non-active surfaces in which no electronic circuits are formed. Active surfaces of the first chip 11, the second chip 12, and the third chip 13 may be formed on lower surfaces of the chips.

According to an embodiment, the second chip 12 may be a logic chip for high-speed signal transmission and having a large number of input and output pins. The first chip 11 may be a memory chip. The third chip 13 may be a memory chip or a chip having other functions, for example, a micro-electro-mechanical sensor chip.

The second chip 12 may be a flip chip to be connected to the substrate 10 through the plurality of solder bumps 14. An electrical connection between the first chip 11, the second chip 12, and the third chip 13 may be provided by the bonding wires 25, thereby permitting communication between the chips 11, 12, and 13.

As shown in FIG. 13, the first chip 11 and the third chip 13 may be stacked on the second chip 12. Accordingly, the first chip 11 and the third chip 13 may be referred to as stack chips. Although FIG. 13 illustrates the stack semiconductor package structure 300 including two chips, i.e. the first chip 11 and the third chip 13, stack chips may be greater than two as will be described later.

According to an embodiment, the stack semiconductor package structure 300 may further include the encapsulant 16 and the solder balls 17 attached to the lower surface 10b of the substrate 10. The encapsulant 16 may protect the first chip 11, the second chip 12, the third chip 13, and the substrate 10, etc. The encapsulant 16 may be formed by applying a molding compound around the chips 11, 12, and 13 and the substrate 10. The solder balls 17 may be formed on the solder ball pads 17a formed on the lower surface 10b of the substrate 10. Thus, the chips 11, 12, and 13 may be electrically connected to other circuits.

Although FIGS. 11 through 14 illustrate the stack semiconductor package structures 200 and 300 including the first chip 11, the second chip 12 and the third chip 13, the stack semiconductor package structures 200 and 300 may further include more chips, and different chips may be connected to each other through the bonding wires 25. The stack semiconductor package structures 200 and 300 may further include at least one chip positioned on the first chip 11, and different chips may be connected to each other through the bonding wires 25.

If the stack semiconductor package structures 200 and 300 include a plurality of chips, a method of manufacturing the stack semiconductor package structures 200 and 300 according to an embodiment may include: providing at least one chip on a carrier; providing a flip chip having a plurality of solder bumps on an upper surface thereof on the at least one chip; electrically connecting different chips with each another through bonding wires; electrically connecting the flip chip to a substrate in a flip-chip manner through the plurality of solder bumps; and removing the carrier.

An example of a stack semiconductor package structure including three or more stack chips positioned on a flip chip and electrically connected through bonding wires will now be described below.

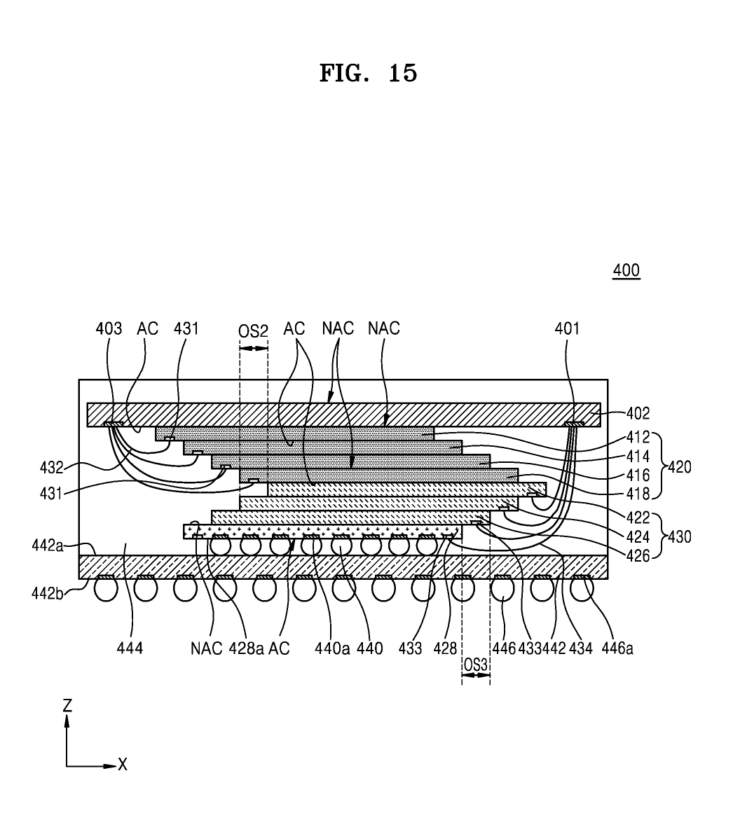

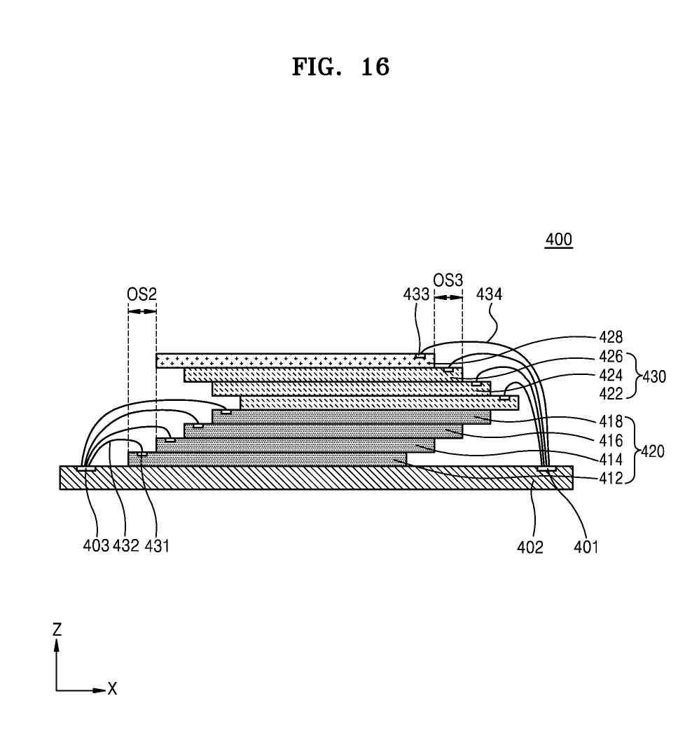

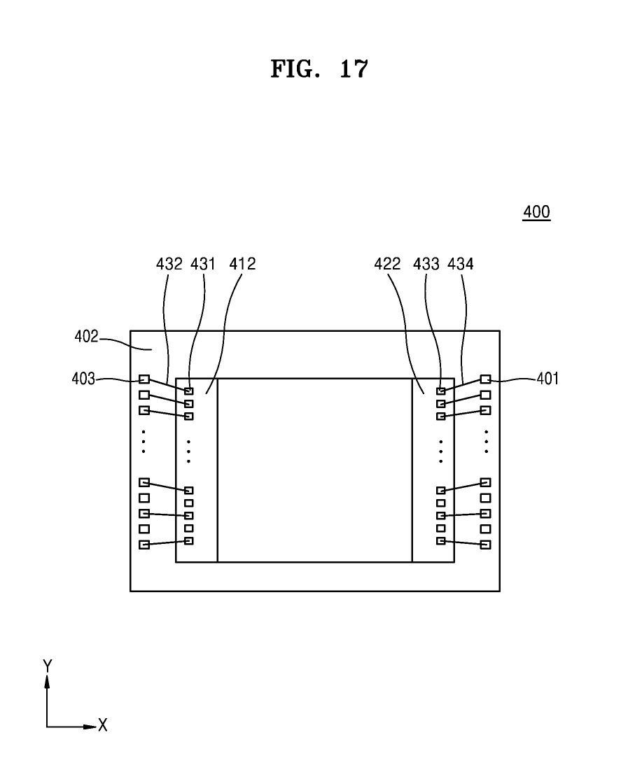

FIG. 15 is a cross-sectional view illustrating a stack semiconductor package structure 400 according to another embodiment. FIGS. 16 and 17 are a cross-sectional view and a plan view, respectively, illustrating a layout relationship of a flip chip and stack chips of FIG. 15.

More specifically, FIG. 15 is a cross-sectional view for describing an overall structure of the stack semiconductor package structure 400. FIG. 16 is a cross-sectional view of the stack semiconductor package structure 400 in which a flip chip 428 and stack chips 430, 420, and 402 of FIG. 15 are flipped in order to place the flip chip 428 on top. FIG. 17 is a plan view illustrating a stack and electrical relationship of the flip chip 428 and the stack chips 430, 420, and 402 of FIG. 16.

The stack semiconductor package structure 400 may include, as shown in FIG. 15, a substrate 442, the flip chip 428 having a plurality of solder bumps 440 formed on a surface thereof, and the stack chips 430, 420, and 402 positioned above the flip chip 428.

The flip chip 428 may include an active surface AC in which electronic circuits are formed and a non-active surface NAC in which no electronic circuits are formed. The active surface AC of the flip chip 428 may be formed in a lower direction. The flip chip 428 may be electrically connected to the substrate 442 in a flip-chip manner through the solder bumps 440 on solder bump pads 440a. The solder bumps 440 may include solder components, cooper pillars, gold bumps and so on.

As shown in FIG. 15, the stack chips 430, 420, and 402 may be stacked on the flip chip 428. The stack chips 430, 420, and 402 may include the active surfaces AC in which electronic circuits are formed and the non-active surfaces NAC in which no electronic circuit is formed. The active surfaces AC of the stack chips 430, 420, and 402 may be formed on a lower surface of the chips. The stack semiconductor package structure 400 of FIG. 15 may include a plurality of chips, e.g. eight (8) chips, as the stack chips 430, 420, and 402 but the inventive concept is not limited thereto. For example, more than 8 chips may be used to form the stack semiconductor package structure.

The stack chips 430, 420, and 402 may include a second chip group 430, a first chip group 420, and a third chip 402, which are sequentially stacked on the flip chip 428. The second chip group 430 may include, but is not limited to, second sub chips 426, 424, and 422. In other words, there may be more or fewer than three sub chips in the second chip group 430.

The first chip group 420 may include, but is not limited to, first sub chips 418, 416, 414, and 412. In other words, there may be more or fewer than four sub chips in the second chip group 430.

The second sub chips 426, 424, and 422 constituting the second chip group 430 may be stacked on the flip chip 428 having a second offset OS3. For example, the second sub chips 426, 424, and 422 may be stacked stepwise to have the second offset OS3 in a first direction, which may be a horizontal direction (X direction) on the flip chip 428. Accordingly, bonding pads 433 of the flip chip 428 and the second sub chips 426, 424, and 422 may be exposed.

The first sub chips 418, 416, 414, and 412 constituting the first chip group 420 may be stacked to have a first offset OS2 on the second chip group 430. The first sub chips 418, 416, 414, and 412 may be stacked stepwise to have the first offset OS2 in a second direction that is opposite to the first direction, for example, an opposite horizontal direction (−X direction) on the second chip group 430. Accordingly, bonding pads 431 of the first sub chips 418, 416, 414, and 412 may be exposed.

The flip chip 428 and the second sub chips 426, 424, and 422 constituting the second chip group 430 may be electrically connected to the third chip 402 through bonding wires 434. That is, the bonding pads 433 of the flip chip 428 and the second chip group 430 may be electrically connected to a bonding pad 401 (located on a right side in FIG. 15) of a third chip 402 through the bonding wires 434.

The first sub chips 418, 416, 414, and 412 constituting the first chip group 420 may be electrically connected to the third chip 402 through bonding wires 432. That is, the bonding pads 431 of the first sub chips 418, 416, 414, and 412 constituting the first chip group 420 may be electrically connected to another bonding pad 403 (located on a left side in FIG. 15) of the third chip 402 through the bonding wires 432.

As explained with respect to FIG. 15, the plurality of bonding wires 432 and 434 may be connected to the corresponding bonding pads 401 and 403 of the third chip 402. With such connections, the first chip group 420 and the second chip group 430 may communicate through the bonding wires 432 and 434. As illustrated in FIG. 15, the flip chip 428 may be mounted on a portion of the substrate 442, and the bonding wires 432 and 434 may not contact an upper surface 442a of the substrate 442. The bonding wires 432 and 434 may not be electrically connected to the substrate 442 and may be spaced apart therefrom.

The substrate 442 may include a printed circuit board (PCB), a silicon substrate, a sapphire substrate or the like, but the inventive concept is not limited to the substrate 442 described above. As will be recognized by those skilled in the art, any suitable material may be selected for the substrate 442 and is within the spirit and scope of the inventive concept.

According to an embodiment, the flip chip 428 may be a chip for a high-speed signal. The flip chip 428 may be a logic chip processing the high-speed signal and including many input pins and output pins. The solder bumps 440 may be formed on a lower surface 428a of the flip chip 428.

According to an embodiment, the first sub chips 418, 416, 414, and 412 constituting the first chip group 420 and the second sub chips 426, 424, and 422 constituting the second chip group 430 may be memory chips. Although not illustrated in FIGS. 15 and 16, the flip chip 428 may be attached to the first chip group 420 and the second chip group 430 by an adhesive.

The stack semiconductor package structure 400 may further include an encapsulant 444 protecting the flip chip 428, the second chip group 430, the first chip group 420, the third chip 402, the substrate 442 and so on. The encapsulant 444 may be provided by applying a molding compound around the second chip group 430, the first chip group 420, the third chip 402, and the substrate 442.

The stack semiconductor package structure 400 may further include solder balls 446 disposed in a lower surface 442b of the substrate 442. For example, the solder balls 446 may be formed in the lower surface 442b of the substrate 442 through a bumping process. Thus, the flip chip 428, the second chip group 430, the first chip group 420, and the third chip 402 may be electrically connected to other circuits. In FIG. 15, reference numeral 446a may be a solder ball pad.

In some embodiments, one of the second chip group 430 and the first chip group 420 is stacked to have an offset on the flip chip 428.

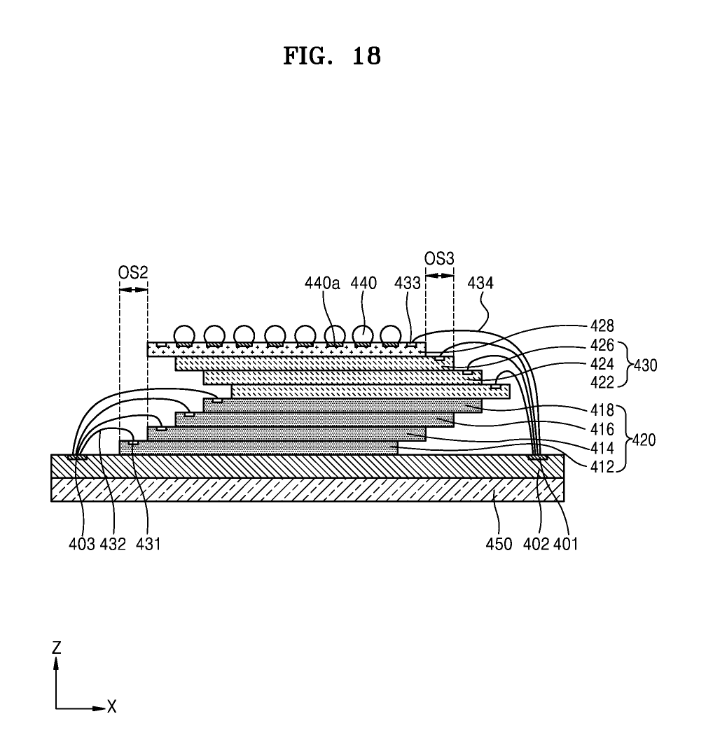

A method of manufacturing the stack semiconductor package structure 400 shown in FIG. 15 will be described in detail with reference to FIGS. 18 through 20 below.

FIGS. 18 through 20 are cross-sectional views for describing a method of manufacturing a stack semiconductor package structure according to some embodiments.

Referring to FIG. 18, the stack chips 402, 420, and 430 and the flip chip 428 may be sequentially formed on a carrier 450. The stack chips 402, 420, and 430 may include the third chip 402, the first chip group 420, and the second chip group 430. The third chip 42 may include the bonding pads 410 and 403.

Although not illustrated in FIG. 18, the third chip 402 may be attached to the carrier 450 using a removable adhesive coated on an upper surface of the carrier 450. Examples of the removable adhesive may include a photosensitive material (for example, a thin film material whose viscosity is reduced by radiation of an ultraviolet light), and a hot melt adhesive, etc.

The first chip group 420 may be stacked on the third chip 402. The first chip group 402 may include the first sub chips 418, 416, 414, and 412. The first sub chips 418, 416, 414, and 412 constituting the first chip group 420 may be stacked on the third chip 402 having the first offset OS2 in a first direction, for example, a horizontal direction (X direction). Accordingly, the bonding pads 431 of the first sub chips 418, 416, 414, and 412 may be exposed.

The second chip group 430 and the flip chip 428 may be sequentially stacked on the first chip group 420. The flip chip 428 may be stacked on second sub chips 426, 424, and 422 constituting the second chip group 430. The second sub chips 426, 424, and 422 constituting the second chip group 430 may be stacked stepwise to have the second offset OS3 in a second direction that is opposite to the first direction, for example, an opposite horizontal direction (−X direction) on the first chip group 420. Accordingly, the bonding pads 433 of the flip chip 428 and the second sub chips 426, 424, and 422 may be exposed.

The solder bumps 440 may be formed on an upper surface 428a of the flip chip 428. The solder bumps 440 may be formed on corresponding ones of the solder bump pads 444a.

The first sub chips 418, 416, 414, and 412 constituting the first chip group 420 may be electrically connected to the third chip 402 through the bonding wires 432. The bonding pad 431 of the first chip group 420 and the bonding pad 403 of the third chip 402 may be electrically connected to each other through the bonding wires 432.

The second sub chips 426, 424, and 422 constituting the second chip group 430 may be electrically connected to the third chip 402 through the bonding wires 434. The bonding pad 433 of the second chip group 430 and the bonding pad 401 of the third chip 402 may be electrically connected to each other through the bonding wires 434.

As shown in FIG. 18, the highest point of each of the bonding wires 434 may be lower than a highest point of the solder bumps 440 on the flip chip 428 to prevent the bonding wires 434 from contacting the substrate 442 during a subsequent flip-chip bonding process.

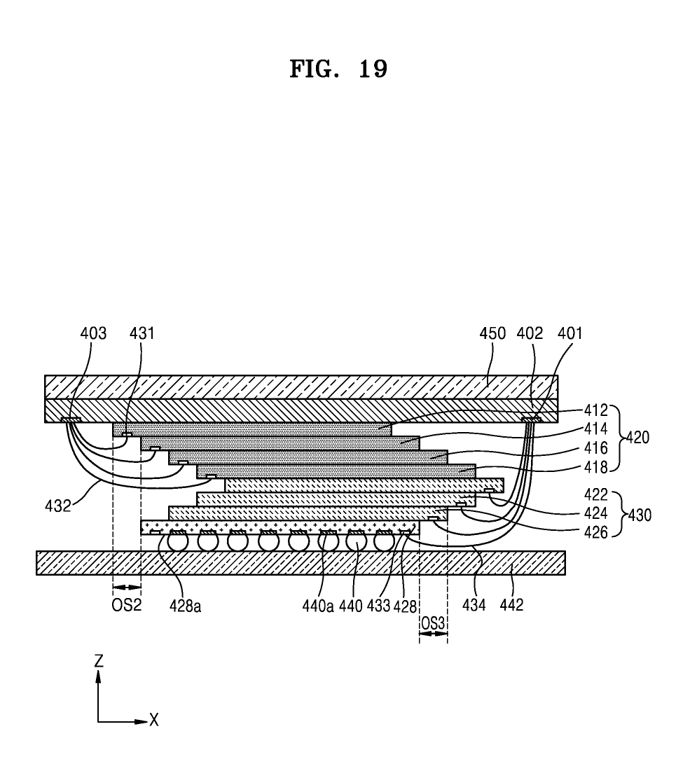

Referring to FIG. 19, the stack chips 402, 420, and 430 and the flip chip 428 sequentially formed on the carrier 450 may be flipped in comparison with FIG. 18. The flip chip 428 that is flipped may be electrically connected to the substrate 442 in a flip-chip manner through the solder bumps 440. The bonding wires 434 may not be in contact with the substrate 442 and may be spaced apart from the substrate 442. If the flip chip 428 is a logic chip, the logic chip having many input and output pins may be electrically connected to the substrate 442 in a flip-chip manner

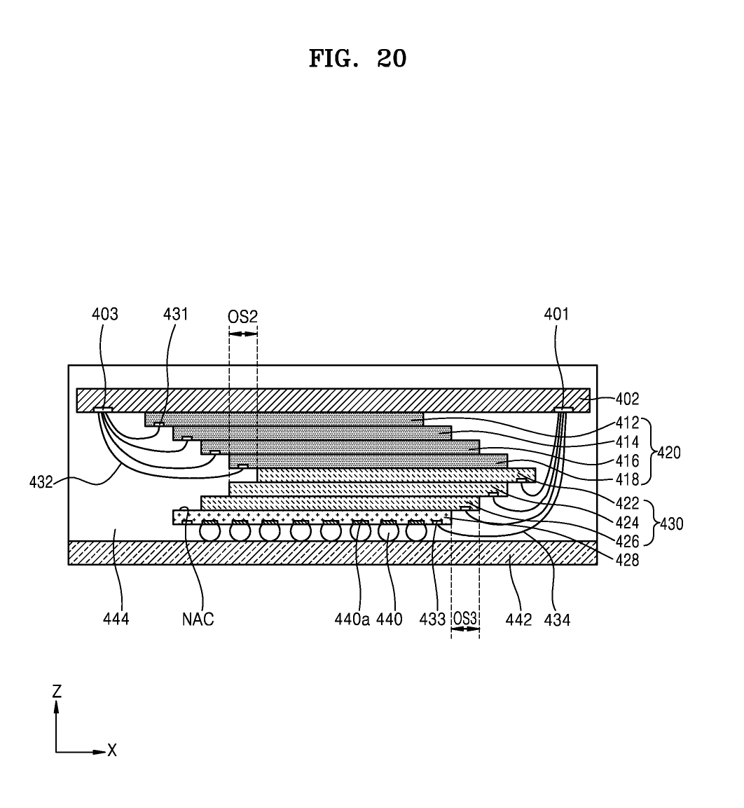

As shown in FIG. 20, the carrier 450 may be removed. For example, the carrier 450 may be removed by melting a hot melt adhesive by heating. The carrier 450 may be removed by reducing viscosity of a photosensitive adhesion layer by radiation of an ultraviolet light. However, the inventive concept is not limited thereto.

The flip chip 428, the stack chips 402, 420, and 430, and the substrate 442 may be encapsulated by an encapsulant 444 using a molding process. The encapsulant 444 is configured to protect the flip chip 428, the stack chips 402, 420, and 430, and the substrate 442.

Then, as shown in FIG. 15, the solder balls 446 may be formed in a lower surface of the substrate 442. For example, the solder balls 446 may be formed on the lower surface of the substrate 442 through a bumping process such that the flip chip 428 and the stack chips 402, 420, and 430 may be connected to other circuits.

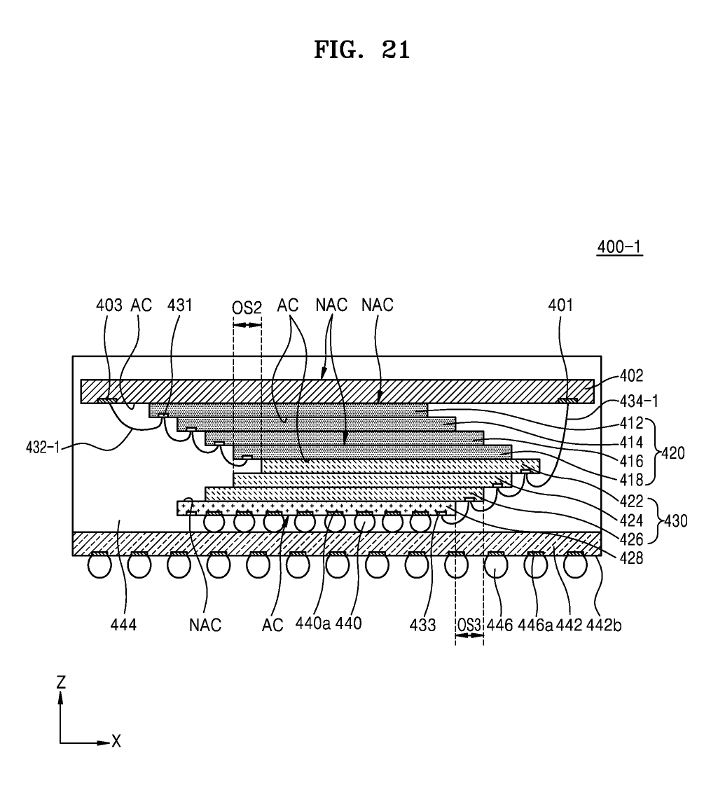

FIG. 21 is a cross-sectional view illustrating a stack semiconductor package structure 400-1 according to another embodiment.

More specifically, the stack semiconductor package structure 400-1 of FIG. 21 may be the same as the stack semiconductor package structure 400 of FIG. 15, except for an electrical connection relationship between the flip chip 428, the second chip group 430, and the third chip 402, and an electrical connection relationship between the first chip group 420 and the third chip 402.

Descriptions of elements of the stack semiconductor package structure 400-1 of FIG. 21 may be omitted or briefly provided with reference to the stack semiconductor package structure 400 of FIG. 15. Differences between the stack semiconductor package structure 400-1 of FIG. 21 and the stack semiconductor package structure 400 of FIG. 15 will be more fully explained.

The stack semiconductor package structure 400-1 may include the substrate 442, the flip chip 428 having the plurality of solder bumps 440 formed on a surface thereof, and the stack chips 430, 420, and 402 positioned above the flip chip 428.

The flip chip 428 and the stack chips 430, 420, and 402 may include the active surface AC in which electronic circuits are formed and the non-active surface NAC in which no electronic circuits are formed. The active surface AC of the flip chip 428 and the stack chips 430, 420, and 402 may be formed in a lower direction or on a lower surface of the chips.

The flip chip 428 may be electrically connected to the substrate 442 in a flip-chip manner through the solder bumps 440 on solder bump pads 440a. The solder bumps 440 may include solder components, cooper pillars, and gold bumps, etc.

The stack chips 430, 420, and 402 may include the second chip group 430, the first chip group 420, and the third chip group 402 that are stacked on the flip chip 428. The second chip group 430 may include the second sub chips 426, 424, and 422. The first chip group 420 may include the first sub chips 418, 416, 414, and 412.

The second sub chips 426, 424, and 422 constituting the second chip group 430 may be stacked to have the second offset OS3 on the flip chip 428. The first sub chips 418, 416, 414, and 412 constituting the first chip group 420 may be stacked to have the first offset OS2 on the second chip group 430.

The flip chip 428 and the second sub chips 426, 424, and 422 may be electrically connected to each other through bonding wires 434-1. The second sub chip 422 may be electrically connected to the third chip 402 through the bonding wires 434-1. The flip chip 428 may be electrically connected to the chip 402 sequentially through the second sub chips 426, 424, and 422.

The first sub chips 418, 416, 414, and 412 may be electrically connected to each other through the bonding wires 432-1. The first sub chip 412 may be electrically connected to the third chip 402 through the bonding wires 432-1. The third chip 402 may be electrically connected to the flip chip 428 through the second chip group 430. The stack semiconductor package structure 400-1 may communicate between the chip groups 420 and 430 and the third chip 402 through the bonding wires 432-1 and 434-1 and the third chip 402.

The stack semiconductor package structure 400-1 may further include the encapsulant 444 protecting the flip chip 428, the second chip group 430, the first chip group 420, the third chip 402, and the substrate 442, etc. The stack semiconductor package structure 400-1 may further include the solder balls 446 disposed in a lower surface 442b of the substrate 442.

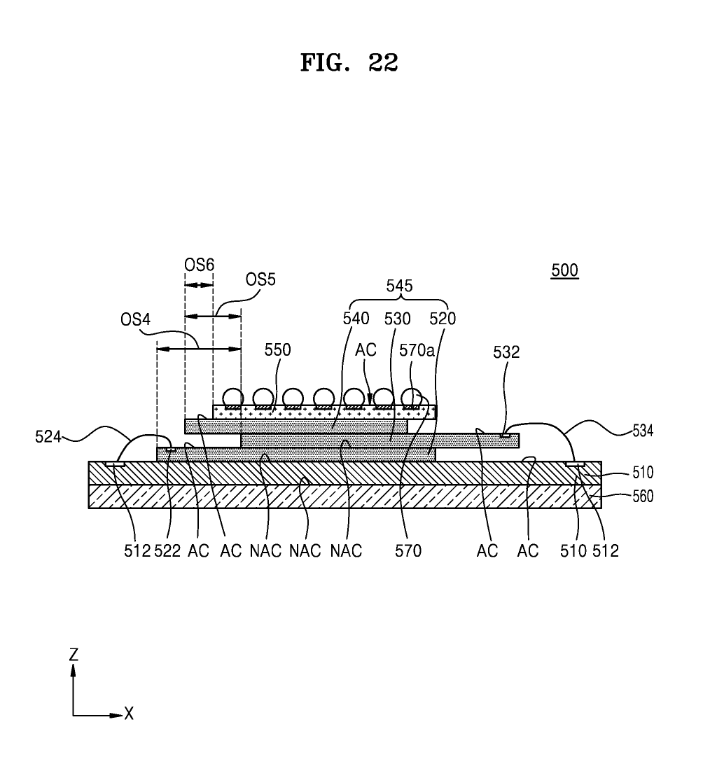

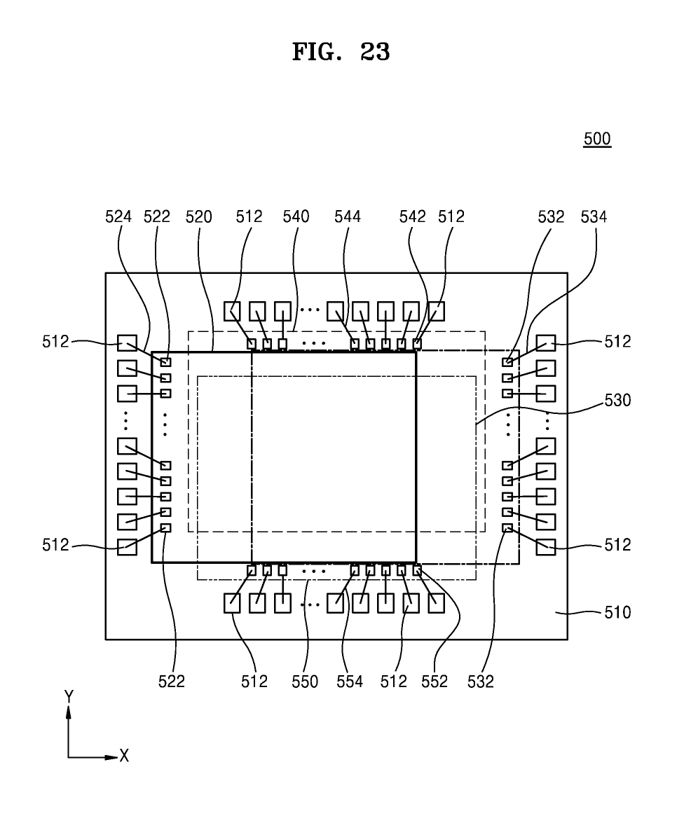

FIG. 22 is a cross-sectional view illustrating a stack semiconductor package structure 500 according to another embodiment. FIG. 23 is a plan view for illustrating an arrangement of a flip chip and stack chips of FIG. 22.

More specifically, FIG. 22 is a cross-sectional view for describing the stack semiconductor package structure 500. The stack semiconductor package structure 500 of FIG. 22 may include only stack chips 510 and 545 and a flip chip 550 sequentially mounted on a carrier 560 for the sake of convenience. FIG. 23 is a plan view for illustrating a stack and electrical relationship of the stack chips 510 and 545 and the flip chip 550 of FIG. 22.

The stack semiconductor package structure 500 may include the stack chips 510 and 545 and the flip chip 550 stacked on the stack chips 510 and 545 and having a plurality of solder bumps 570 formed on a surface thereof. The flip chip 550 may be electrically connected to the substrate 442 through the solder bumps 570 as described with reference to FIGS. 15 through 21.

The stack chips 510 and 545 may include a fourth chip 510 and a fifth chip group 545 including first through third chips 520, 530, and 540. The stack semiconductor package structure 500 of FIG. 22 may include a plurality of chips, e.g. three (3) chips, as the stack chips 510 and 545 but the inventive concept is not limited thereto. The fifth chip group 545 includes three chips but the inventive concept is not limited thereto. For example, the fifth chip group 545 may include more or fewer than three chips.

The fourth chip 510, chips in the fifth chip group 545, and the flip chip 550 may include the active surfaces AC in which electronic circuits are formed and the non-active surfaces NAC in which no electronic circuits are formed.

Because the fourth chip 510, the fifth chip group 545, and the flip chip 550 are sequentially stacked on the carrier 560, the active surface AC can be positioned on an upper side of the fourth chip 510, chips in the fifth chip group 545, and the flip chip 550. The flip chip 550 may be electrically connected to the substrate 442 of FIGS. 15 and 21 through the solder bumps 570, which are formed on corresponding ones of the solder bump pads 570a.

As shown in FIG. 22, the fifth chip group 545 including the first through third chips 520, 530, and 540 and the flip chip 550 may be sequentially stacked on the fourth chip 510. The second chip 530, the third chip 540, and the flip chip 550 may be stacked on the first chip 520 having offsets OS4, OS5, and OS6.

The second chip 530 may be stacked with the offset OS4 on the first chip 520 in a horizontal direction (X direction). The third chip 540 may be stacked stepwise to have the offset OS5 on the second chip 530 in an opposite horizontal direction (−X direction). The flip chip 550 may be stacked with the offset OS6 on the third chip 540 in the horizontal direction (X direction). Accordingly, bonding pads 522, 532, and 542 of the chip group 545 including the first through third chips 520, 530, and 540 and bonding pads 552 of the flip chip 550 may be exposed. FIG. 22 is a cross-sectional view of FIG. 23 in the horizontal direction (X direction), and thus the bonding pad 542 of the third chip 540 and the bonding pads 552 of the flip chip 550 are not illustrated.

The bonding pad 522 of the first chip 520 may be electrically connected to the bonding pad 512 of the fourth chip 510 through bonding wires 524. The bonding pad 532 of the second chip 530 may be electrically connected to the bonding pad 512 of the fourth chip 510 through bonding wires 534. The bonding pad 542 of the third chip 530 may be electrically connected to the bonding pad 512 of the fourth chip 510 through bonding wires 544. The bonding pad 552 of the flip chip 550 may be electrically connected to the bonding pad 512 of the fourth chip 510 through bonding wires 554.

The chip group 545 including the first through third chips 520, 530, and 540 and the flip chip 550 may communicate with the fourth chip 510 through the bonding wires 522, 532, 542, and 552. According to some embodiments, the flip chip 550 may be a chip for a high-speed signal. The flip chip 550 may be a logic chip processing the high-speed signal and including a large number of input pins and output pins.

According to an embodiment, the first through third chips 520, 530, and 540 may be memory chips. The fourth chip 510 may be a memory chip or a chip having other functions, for example, a micro-electro-mechanical sensor chip.

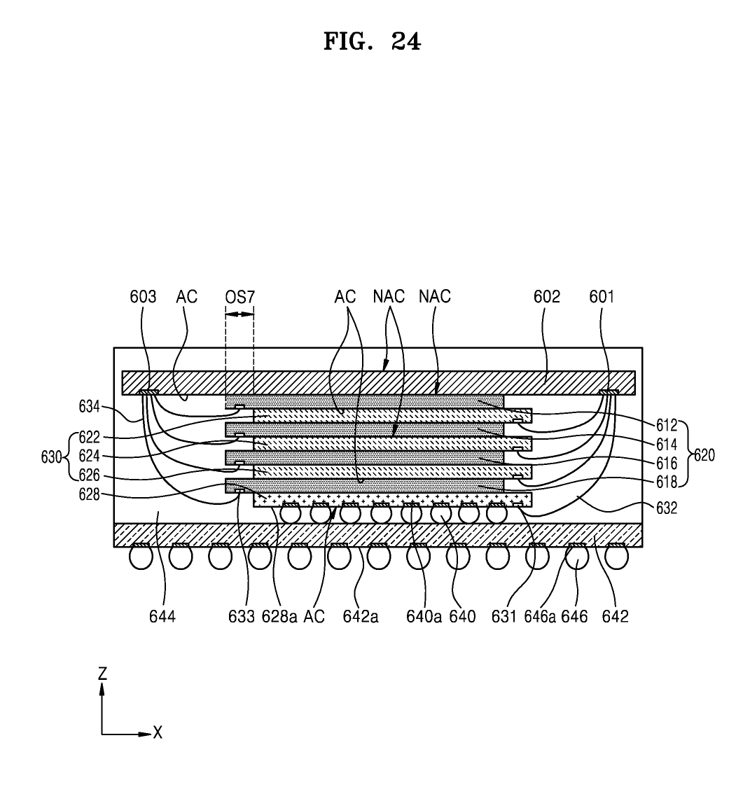

FIG. 24 is a cross-sectional view illustrating a stack semiconductor package structure 600 according to another embodiment.

More specifically, the stack semiconductor package structure 600 may include a substrate 642, a flip chip 628 having a plurality of solder bumps 640 formed on a bottom surface 628a thereof, and stack chips 630, 520, and 602 stacked on the flip chip 628.

The flip chip 628 and the stack chips 630, 620, and 602 may include the active surfaces AC in which electronic circuits are formed and the non-active surfaces NAC in which no electronic circuits are formed. The active surfaces AC of the flip chip 628 and the stack chips 630, 520, and 602 may be formed on a lower or bottom surface of the chips.

The flip chip 628 may be electrically connected to the substrate 642 in a flip-chip manner through the solder bumps 640 on the solder bump pads 640a. The solder bumps 640 may include solder components, cooper pillars, and gold bumps, etc.

As shown in FIG. 24, the stack chips 630, 520, and 602 may be stacked on the flip chip 628. The stack semiconductor package structure 600 of FIG. 24 includes a plurality of chips, e.g. eight (8) chips, as the stack chips 630, 520, and 602 but the inventive concept is not limited thereto.

The stack chips 630, 520, and 602 may include a first chip group 620, a second chip group 630, and a third chip 602 that are stacked on the flip chip 628. The first chip group 620 may include first sub chips 618, 616, 614, and 612. The second chip group 630 may include three second sub chips 626, 624, and 622 but the inventive concept is not limited thereto. The first chip group 620 may include the four first sub chips 618, 616, 614, and 612 but the inventive concept is not limited thereto. The first sub chips 618, 616, 614, and 612 and the second sub chips 626, 624, and 622 may be alternately stacked on the flip chip 628.

The first sub chips 618, 616, 614, and 612 constituting the first chip group 620 may be stacked with an offset OS7 on the flip chip 628. The first sub chips 618, 616, 614, and 612 may be stacked with the offset OS7 on the flip chip 628 in a horizontal direction (X direction). Accordingly, bonding pads 633 of the first sub chips 618, 616, 614, and 612 may be exposed.

The second sub chips 626, 624, and 622 constituting the second chip group 630 may be stacked not to have an offset on the flip chip 628. Accordingly, bonding pads 631 of the second sub chips 626, 624, and 622 may be exposed. Although the first chip group 620 that is one of the first chip group 620 and the second chip group 630 may be configured to have an offset on the flip chip 628 in FIG. 24, the second chip group 630 may be configured to have an offset on the flip chip 628 as necessary.

The flip chip 628 and the second sub chips 626, 624, and 622 constituting the second chip group 630 may be electrically connected to the third chip 602 through bonding wires 631. That is, the bonding pads 631 of the flip chip 628 and the second chip group 630 may be electrically connected to a bonding pad 601 of the third chip 602 through the bonding wires 632.

The first sub chips 618, 616, 614, and 612 constituting the first chip group 620 may be electrically connected to the third chip 602 through bonding wires 634. That is, bonding pads 633 of the first sub chips 618, 616, 614, and 612 constituting the first chip group 620 may be electrically connected to a bonding pad 603 of the third chip 602 through the bonding wires 634.

The first chip group 620 and the second chip group 630 may communicate through the bonding wires 632 and 634. As illustrated in FIG. 24, the bonding wires 632 and 634 may not be in contact with an upper surface of the substrate 642 and may be spaced apart from the substrate 642. The bonding wires 632 and 634 may not be electrically connected to the substrate 642

The substrate 642 may include a printed circuit board (PCB), a silicon substrate, a sapphire substrate or the like, but the inventive concept is not limited to the substrate 642 described above. As will be recognized by those skilled in the art, any suitable material may be selected for the substrate 642 and is within the spirit and scope of the inventive concept. According to an embodiment, the flip chip 628 may be a chip for a high-speed signal. The flip chip 628 may be a logic chip processing the high-speed signal and including a large number of input pins and output pins. The solder bumps 640 may be formed on a lower surface of the flip chip 628.

The first sub chips 618, 616, 614, and 612 constituting the first chip group 620 and the flip chip 628 and the second sub chips 626, 624, and 622 constituting the second chip group 630 may be memory chips. Although not illustrated in FIG. 24, the flip chip 628 may be attached to the first chip group 620 and the second chip group 630 by an adhesive.

The stack semiconductor package structure 600 may further include an encapsulant 644 protecting the flip chip 628, the second chip group 630, the first chip group 620, the third chip 602, and the substrate 642, etc. The encapsulant 644 may be provided by applying a molding compound around the second chip group 630, the first chip group 620, the third chip 602, and the substrate 642.

The stack semiconductor package structure 600 may further include solder balls 646 disposed on a lower surface 642a of the substrate 642. For example, the solder balls 646 may be formed on the lower surface 642a of the substrate 642 through a bumping process. Thus, the flip chip 628, the second chip group 630, the first chip group 620, and the third chip 602 may be electrically connected to other circuits. In FIG. 24, reference numeral 646a may be a solder ball pad.

In some embodiments, although the present inventive concept has been implemented using a bonding wire, any other suitable conductive connection member can be used instead to implement the inventive concept within the spirit and scope of the inventive concept. For example, a suitable conductive trace or line can be formed extending between bonding pads of stack chips.

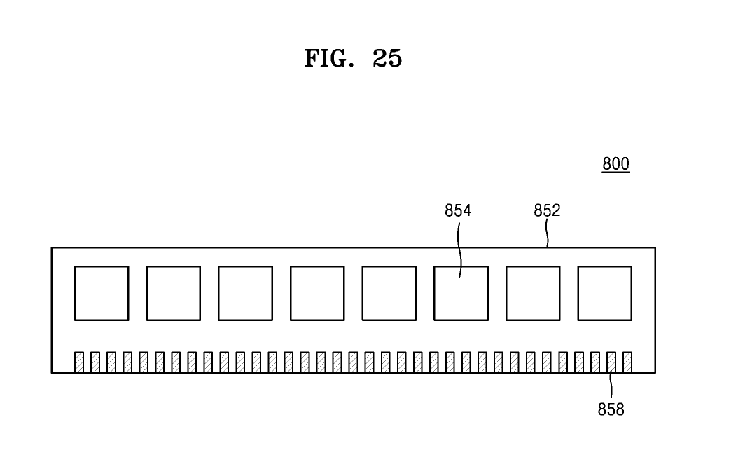

FIG. 25 is a schematic plan view of a semiconductor module 800 including a semiconductor package according to an embodiment.

In detail, the semiconductor module 800 may include a module substrate 852, a plurality of semiconductor packages 854 arranged on the module substrate 852, and module contacting terminals 858 that are formed along an edge of the module substrate 852 and electrically connected to the respective semiconductor packages 854.

The module substrate 852 may be a printed circuit board (PCB). Both surfaces of the module substrate 852 may be used. In other words, the semiconductor packages 854 may be arranged on both the front surface and the rear surface of the module substrate 852. FIG. 46 shows that the eight semiconductor packages 854 are arranged on the front surface of the module substrate 852. However, the inventive concept is not limited to this embodiment, but it is merely one exemplary embodiment. The semiconductor module 800 may further include a separate semiconductor package for controlling the semiconductor packages 854.

At least one of the semiconductor packages 854 may be a semiconductor package according to the above-stated embodiments. The module contacting terminals 858 may be formed of a metal and may be oxidization-resistant. The module contacting terminals 858 may be configured according to standard specifications of the semiconductor module 800. Therefore, the number of the module contacting terminals 858 shown in FIG. 25 is merely and is not limiting.

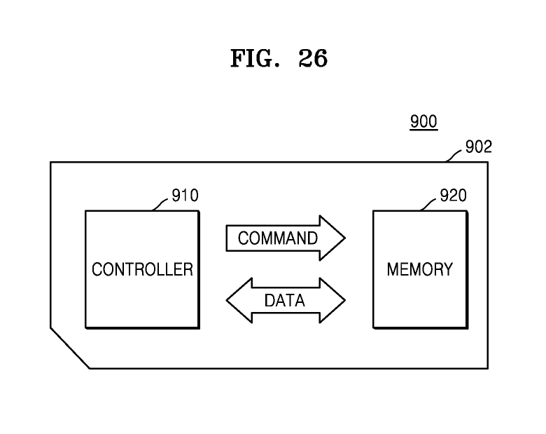

FIG. 26 is a schematic diagram showing a card 900 including a stack semiconductor package structure according to an embodiment.

In detail, the card 900 may include a controller 910 and a memory 920 arranged on a circuit board 902. The controller 910 and the memory 920 may be arranged to exchange electric signals. For example, when the controller 910 issues a command, the memory 920 may transmit data. The memory 920 or the controller 910 may include a stack semiconductor package structure according to an embodiment.

The card 900 may be one of various types of cards, e.g., a memory stick card, a smart media card (SM), a secure digital card (SD), a mini secure digital card (mini SD), or a multimedia card (MMC).

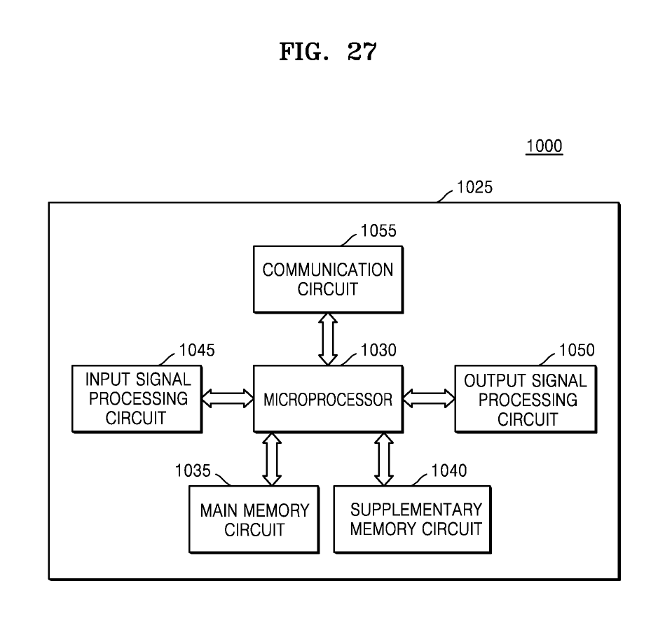

FIG. 27 is a schematic block diagram showing an electronic circuit board 1000 including a stack semiconductor package structure according to an embodiment.

In detail, the electronic circuit board 1000 may include a microprocessor 1030, a main memory circuit 1035 and a supplementary memory circuit 1040 that communicate with the microprocessor 1030, an input signal processing circuit 1045 that sends a command to the microprocessor 1030, an output signal processing circuit 1050 that receives a command from the microprocessor 1030, and a communication circuit 1055 that exchanges electric signals with other circuit boards, where the above-states components are formed on a circuit board 1025. The arrows may be understood as paths through which electric signals may be transmitted.

The microprocessor 1030 may receive and process various electric signals, output processing results, and control the other components of the electronic circuit board 1000. The microprocessor 1030 may be understood as a central processing unit (CPU) and/or a main control unit (MCU), for example.

The main memory circuit 1035 may temporarily store data always or frequently needed by the microprocessor 1030 or data before/after being processed. Since fast response is demanded to the main memory circuit 1035, the main memory circuit 1035 may include a semiconductor memory chip. In detail, the main memory circuit 1035 may be a semiconductor memory referred to as a cache, a static random access memory (SRAM), a dynamic random access memory (DRAM), a resistive random access memory (RRAM), or an applications thereof (e.g., an utilized RAM, a ferro-electric RAM, a fast cycle RAM, a phase changeable RAM, a magnetic RAM, and one of other semiconductor memories).

In addition, the main memory circuit 1035 may be volatile or non-volatile and may include a random access memory. According to some embodiments, the main memory circuit 1035 may include a stack semiconductor package structure according to an embodiment. The supplementary memory circuit 1040 is a large-capacity memory element and may be a non-volatile semiconductor memory, such as a flash memory, or a hard disk drive using a magnetic field. Alternatively, the supplementary memory circuit 1040 may be a compact disc drive using lights. Compared to the main memory circuit 1035, the supplementary memory circuit 1040 may be used when it is necessary to store a large amount of data, where a fast response is not demanded. The auxiliary memory circuit 1240 may be random or non-random memory and may include a non-volatile memory element.

The supplementary memory circuit 1040 may include a stack semiconductor package structure according to an embodiment. The input signal processing circuit 1045 may convert an external command to an electric signal or may transmit an electric signal transmitted from outside to the microprocessor 1030.

A command or an electric signal transmitted from the outside may be an operation command, an electric signal to process, or data to be stored. The input signal processing circuit 1045 may be a terminal signal processing circuit for processing signals transmitted from a keyboard, a mouse, a touch pad, an image recognizing apparatus, or various sensors, an image signal processing unit for processing image signals input via a scanner or a camera, or an interface for various sensors or receiving input signals. The input signal processing circuit 1045 may include a stack semiconductor package structure according to an embodiment.

The output signal processing circuit 1050 may be a component for outputting electric signals processed by the microprocessor 1030 to outside. For example, the output signal processing circuit 1050 may be a graphic card, an image processor, an optical converter, a beam-panel card, or interface circuits having various functions. The output signal processing circuit 1050 may include a stack semiconductor package structure according to an embodiment.

The communication circuit 1055 may be a component for directly transmitting and receiving electric signals to and from another electronic system or another circuit board without an input signal processing circuit 1245 or an output signal processing circuit 1250. For example, the communication circuit 1055 may be a modem for a personal computer system, a LAN card, or one of various interface circuits. The communication circuit 1055 may include a stack semiconductor package structure according to an embodiment.

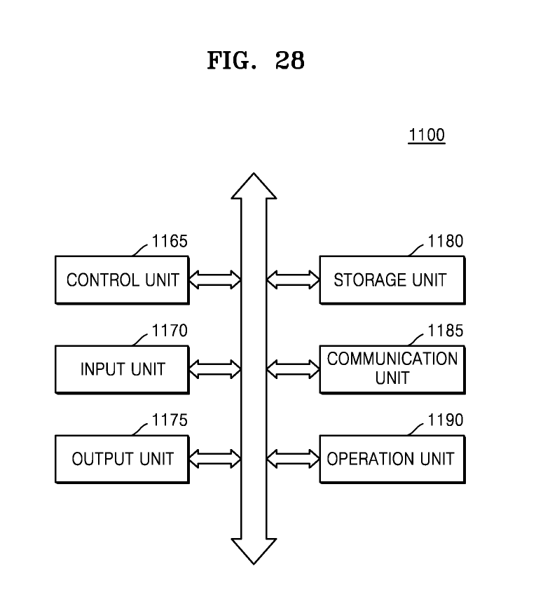

FIG. 28 is a schematic block diagram showing an electronic system 1100 including a stack semiconductor package structure according to an embodiment.

In detail, the electronic circuit board 1100 may include a control unit 1165, an input unit 1170, an output unit 1175, and a storage unit 1180 and may further include a communication unit 1185 and/or an operation unit 1190.

The control unit 1165 may control the electronic system 1100 and the components thereof. The control unit 1165 may be understood as a CPU or a MCU and may include an electronic system (1000 of FIG. 27) according to an embodiment. Furthermore, the control unit 1165 may include a stack semiconductor package structure according to an embodiment.

The input unit 1170 may transmit an electric command signal to the control unit 1165. The input unit 1170 may be a keyboard, a keypad, a mouse, a touch pad, an image recognizing apparatus like a scanner, or one of various sensors. The input unit 1170 may include a stack semiconductor package structure according to some embodiments.

The output unit 1175 may receive an electric command signal from the control unit 1165 and output a result processed by the electronic system 1100. The output unit 1175 may be a monitor, a printer, a beam projector, or one of various other mechanical apparatuses. The output unit 1175 may include a stack semiconductor package structure according to an embodiment.

The storage unit 1180 may be a component for temporarily or permanently storing electric signals to be processed or processed by the control unit 1165. The storage unit 1180 may be physically and/or electrically connected to or combined with the control unit 1165. The storage unit 1180 may be a semiconductor memory, a magnetic storage device like a hard disk drive, an optical storage device like a compact disc drive, or one of other servers having data storage function. Furthermore, the storage unit 1180 may include a stack semiconductor package structure according to an embodiment.

The communication unit 1185 may receive an electric command signal from the control unit 1165 and transmit or receive an electric signal to or from another electronic system. The communication unit 1185 may be a wired transmission/reception device, such as a modem and a LAN card, a wireless transmission/reception device, such as a Wibro interface, or an infrared ray port. Furthermore, the communication unit 1185 may include a stack semiconductor package structure according to an embodiment.

The operation unit 1190 may perform a physical or mechanical operation according to a command from the control unit 1165. For example, the operation unit 1190 may be a component for performing a mechanical operation, such as a floater, an indicator, or an up/down operator. The electronic system 1100 according to an embodiment may be a computer, a network server, a network printer or scanner, a wireless controller, a mobile communication terminal, a switchboard, or one of other electronic devices for performing programmed operations.

Furthermore, the electronic system 1100 may be used in a mobile phone, a MP3 player, a navigation apparatus, a portable multimedia player (PMP), a solid-state disk (SSD), or one of various household appliances.

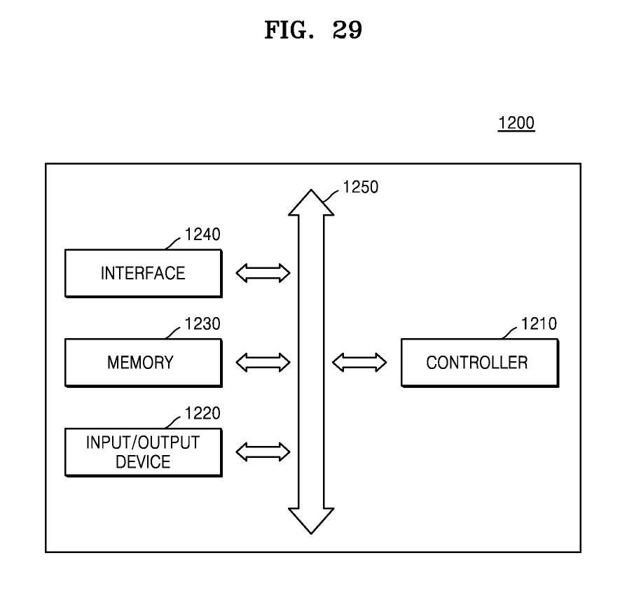

FIG. 29 is a schematic diagram showing an electronic system 1200 including a semiconductor package according to an embodiment.

In detail, the electronic system 1200 may include a controller 1210, an input/output device 1220, a memory 1230, and an interface 1240. The electronic system 1200 may be a mobile system or a system for transmitting or receiving data. The mobile system may be a personal digital assistant (PDA), a portable computer, a web tablet, a wireless phone, a mobile phone, a digital music player, or a memory card.

The controller 1210 may execute a program and control the electronic system 1200. The controller 1210 may include a stack semiconductor package structure according to an embodiment. For example, the controller 1210 may be a microprocessor, a digital signal processor, a microcontroller, or the like.

The input/output device 1220 may be used to input or output data to or from the electronic system 1200. The electronic system 1200 may be connected to an external device, e.g., a personal computer or a network, via the input/output device 1220 and exchange data with the external device. The input/output device 1220 may be a keypad, a keyboard, or a display apparatus.

The memory 1230 may store codes and/or data for operating the controller 1210 and/or store data processed by the controller 1210. The memory 1230 may include a stack semiconductor package structure according to an embodiment. The interface 1240 may be a data transmission path between the electronic system 1200 and another external apparatus. The controller 1210, the input/output device 1220, the memory 1230, and the interface 1240 may communicate with one another via a bus 1250.

For example, the electronic system 1200 may be used in a mobile phone, a MP3 player, a navigation apparatus, a portable multimedia player (PMP), a solid-state disk (SSD), or one of various household appliances.

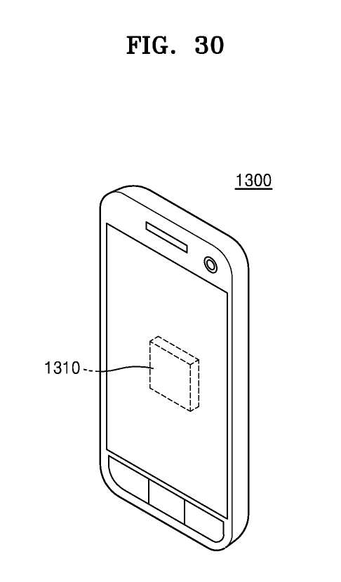

FIG. 30 is a schematic perspective view of an electronic system including a stack semiconductor package structure according to some embodiments.

In detail, FIG. 30 shows an example that the electronic system 1200 of FIG. 29 is applied to a mobile phone 1300. The mobile phone 1300 may include a system-on-chip 1310. The system-on-chip 1310 may include a stack semiconductor package structure according to an embodiment. Since the mobile phone 1300 may include the system-on-chip 1310 at which a relatively high performance main function block may be arranged, the mobile phone 1300 may be a relatively high performance mobile phone 1300. Furthermore, since the system-on-chip 1310 may exhibit relatively high performance at a same area, the mobile phone 1300 may exhibit relatively high performance while size of the mobile phone 1300 is greatly reduced.

While the inventive concept has been particularly shown and described with reference to embodiments thereof, it will be understood that various changes in form and details may be made therein without departing from the spirit and scope of the following claims.

1. A stack semiconductor package structure comprising:
a substrate;
a second chip comprising a plurality of conductive bumps formed on a surface thereof; and
a first chip positioned on the second chip,
wherein the second chip is electrically connected to the substrate through the plurality of conductive bumps in a flip-chip manner, and
wherein the first chip is electrically connected to the second chip through a plurality of bonding wires.

2. The stack semiconductor package structure of claim 1, wherein the plurality of bonding wires are spaced apart from the substrate.

3-5. (canceled)

6. The stacked semiconductor package structure of claim 1, further comprising at least one chip positioned on the first chip,
wherein the first chip, the second chip, and the at least one chip are electrically connected to each other through the plurality of bonding wires.

7. The stacked semiconductor package structure of claim 1, further comprising a third chip positioned on the first chip,
wherein the first chip is electrically connected to the third chip through the plurality of bonding wires.

8. The stacked semiconductor package structure of claim 1, further comprising a third chip positioned on the first chip,
wherein the second chip is electrically connected to the third chip through the plurality of bonding wires.

9. A stack semiconductor package structure comprising:
a substrate;
a flip chip mounted on the substrate and electrically connected to the substrate through a plurality of conductive bumps; and
at least one stack chip attached on the flip chip and electrically connected to the flip chip through a plurality of bonding wires.

10. The stack semiconductor package structure of claim 9, wherein the at least one stack chip is arranged to substantially entirely cover the flip chip.

11. The stack semiconductor package structure of claim 9, wherein one of lengths of the at least one stack chip in a horizontal direction and in a vertical direction is smaller than lengths of the flip chip in the horizontal direction and in the vertical direction, and
wherein the at least one stack chip is arranged to partially cover the flip chip.

12. (canceled)

13. The stack semiconductor package structure of claim 9, wherein the at least one stack chip comprises a plurality of chips, and
wherein one of the plurality of chips is stacked with an offset on the flip chip.

14. The stack semiconductor package structure of claim 13, wherein the plurality of chips included in the at least one stack chip comprise a second chip group, a first chip group, and a third chip that are sequentially stacked on the flip chip,
wherein one of the second chip group and the first chip group is stacked to have an offset on the flip chip, and
wherein the second chip group and the first chip group are electrically connected to the third chip through the plurality of bonding wires.

15. The stack semiconductor package structure of claim 9, wherein the at least one stack chip comprises a plurality of chips,
wherein the plurality of chips are stacked stepwise with an offset on the flip chip.

16. The stack semiconductor package structure of claim 15, wherein the plurality of chips included in the at least one stack chip comprises:
a second chip group stacked stepwise to have a second offset in a first direction on the flip chip;
a first chip group stacked stepwise to have a first offset in a second direction opposite to the first direction on the second chip group; and
a third chip stacked on the first chip group, and
wherein the second chip group and the first chip group are electrically connected to the third chip through the plurality of bonding wires.

17. The stack semiconductor package structure of claim 16, wherein a plurality of sub chips included in the second chip group are electrically connected to each other through the plurality of bonding wires, and
wherein a plurality of sub chips included in the first chip group are electrically connected to each other through the plurality of bonding wires

18. The stack semiconductor package structure of claim 9, wherein the flip chip is mounted on a part of the substrate, and
wherein the plurality of bonding wires are spaced apart from the substrate.

19-32. (canceled)

33. A stack semiconductor package structure comprising:
a package substrate;
a second chip flip-chip bonded to the package substrate; and
a first chip stacked on the second chip,
wherein a portion of the first chip is not overlapped with the second chip, exposing a portion of an upper surface of the first chip, and
wherein the first chip is electrically connected to the second chip through a conductive connection member extending between the exposed upper surface of the first chip and a bonding pad of the second chip.

34. The stack semiconductor package structure of claim 33, wherein the conductive connection member is spaced apart from the substrate.

35. The stack semiconductor package structure of claim 33, wherein the first chip substantially entirely covers the second chip in plan view.

36. The stack semiconductor package structure of claim 33, wherein the conductive connection member comprises a bonding wire.

37. The stack semiconductor package structure of claim 33, further comprising a third chip stacked on the first chip, wherein a bonding pad of the first chip and a bonding pad of the third chip is connected through a bonding wire.

38. The stack semiconductor package structure of claim 33, further comprising a third chip stacked on the first chip, wherein a bonding pad of the third chip and the bonding pad of the second chip is connected through a bonding wire.
